(19) United States
(12) Patent Application Publication
(10) Pub. No.: US 2025/0079411 A1
(43) Pub. Date: Mar. 6, 2025

(54) DISPLAY DEVICE AND METHOD FOR FABRICATING THE SAME

(71) Applicant: Samsung Display Co., LTD., Yongin-si (KR)

(72) Inventors: Yu Jin LEE, Yongin-si (KR); Gwang Geun LEE, Yongin-si (KR); Ki Seong SEO, Yongin-si (KR); Ki Chang EOM, Yongin-si (KR); Jung An LEE, Yongin-si (KR)

(21) Appl. No.: 18/809,867

(22) Filed: Aug. 20, 2024

(30) Foreign Application Priority Data
Aug. 28, 2023 (KR) 10-2023-0112640

(51) Int. Cl. H01L 25/075; H01L 33/10; H01L 33/50; H01L 33/62

(52) U.S. Cl. CPC H01L 25/0753; H10H 20/814; H10H 20/8512; H10H 20/857; H10H 20/0361; H10H 20/0364

(57) ABSTRACT

A display device includes a planarization layer including a first planarization unit on a substrate and a second planarization unit on the first planarization unit, a pixel electrode on the second planarization unit, an organic pattern layer on the pixel electrode, a light emitting element on the organic pattern layer and having a downwardly convex recess on a top surface thereof, a first partition wall on one surface of the first planarization unit and forming a space around the light emitting element, a via layer in the space around the light emitting element, a first reflective layer around a side of the first partition wall in the space around the light emitting element, on the first planarization unit, and around a side of the light emitting element, a side of the organic pattern layer, and a side of the pixel electrode.

### CROSS-REFERENCE TO RELATED APPLICATION

The present application claims priority to and the benefit of Korean Patent Application No. 10-2023-0112640, filed on Aug. 28, 2023, in the Korean Intellectual Property Office, the entire disclosure of which is incorporated by reference herein.

### BACKGROUND

### 1. Field

The present disclosure relates to a display device and a method of manufacturing the same.

### 2. Description of the Related Art

Display devices are becoming increasingly important with the development of multimedia. In response to this, various types of display devices, such as organic light emitting displays (OLED) and liquid crystal displays (LCD), are being used.

### SUMMARY

A display device for displaying an image includes a display panel such as a light emitting display panel or a liquid crystal display panel. Among them, the light emitting display panel may include light emitting elements such as light emitting diodes (LEDs). For example, LEDs include organic light emitting diodes (OLEDs) that utilize organic materials as light emitting materials, inorganic light emitting diodes that utilize inorganic materials as light emitting materials, and the like.

Aspects and features of embodiments of the present disclosure provide a display device and a method of manufacturing the same that efficiently form a reflective layer that may improve the light output efficiency of the light emitting element. Additionally, the display device and the method of manufacturing the same 1 seek to improve power consumption by reducing the contact resistance of the common electrode.

However, aspects and features of embodiments of the present disclosure are not restricted to the one set forth herein. The above and other aspects and features of embodiments of the present disclosure will become more apparent to one of ordinary skill in the art to which the present disclosure pertains by referencing the detailed description of the present disclosure given below.

According to one or more embodiments, a display device includes a planarization layer including a first planarization unit on a substrate and a second planarization unit on the first planarization unit, a pixel electrode on the second planarization unit, an organic pattern layer on the pixel electrode, a light emitting element on the organic pattern layer and having a downwardly convex recess on a top surface thereof, a first partition wall on one surface of the first planarization unit and forming a space around the light emitting element, a via layer in the space around the light emitting element, a first reflective layer around a side of the first partition wall in the space around the light emitting element, on the first planarization unit, and around a side of the light emitting element, a side of the organic pattern layer, and a side of the pixel electrode, an insulating organic layer covering a portion of the upper portion of the light emitting element, an upper portion of the via layer, and a portion of an upper portion of the first partition wall and a common electrode extending along the bottom and side surfaces of the recess on the top surface of the light emitting element, a top surface of the insulating organic layer, and a top surface of the first partition wall, wherein the second planarization unit has an undercut shape in which a side surface of the second planarization unit is located inside a side surface of the pixel electrode, and the first reflective layer has a discontinuous structure due to the undercut shape.

The light emitting element includes a first semiconductor layer, an active layer, a second semiconductor layer, and a third semiconductor layer sequentially 1 stacked, and the recess is formed from a top surface of the third semiconductor layer to the second semiconductor layer toward the second semiconductor layer to expose a portion of the second semiconductor layer, and the common electrode is in direct contact with the exposed portion of the second semiconductor layer.

The light emitting element further includes an element reflective layer on a bottom surface of the first semiconductor layer; an insulating layer around sides of the element reflective layer, the first semiconductor layer, the active layer, the second semiconductor layer, and the third semiconductor layer; and a pad connection electrode on a bottom surface of the element reflective layer and in direct contact with the element reflective layer and the first reflective layer.

The insulating layer is further located on the bottom surface of the element reflective layer and has an opening exposing at least a portion of the element reflective layer, wherein the pad connection electrode contacts the element reflective layer through the opening.

The pad connection electrode electrically connects the first semiconductor layer and the pixel electrode through the element reflective layer and the first reflective layer.

One end of the insulating organic layer meets one end of the recess on the light emitting element.

The recess has a regular tapered shape.

Side surfaces of the light emitting element and side surfaces of the organic pattern layer are aligned with each other.

The pixel electrode protrudes further outward than a side of the organic pattern layer.

The first partition wall has a same height as the light emitting element and has an inverted tapered shape.

The display device further comprises a second partition wall located on the first partition wall, and the second partition wall has a height that is equal to or shorter than that of the first partition wall and has an inverted tapered shape.

The recess has a width of 40% or more of a width of the light emitting element.

The display device further includes a capping layer on the common electrode and covering the common electrode, a second partition wall disposed on the capping layer to overlap the first partition wall, a second reflective layer around a side of the second partition wall, and a wavelength conversion layer disposed in a space formed by the second partition wall.

The display device further includes an overcoat layer and a color filter layer sequentially disposed on the wavelength conversion layer and the second partition wall.

According to one or more embodiments, a method of manufacturing display device includes forming an undercut shape on a substrate on which a first planarization unit, a second planarization unit, and a pixel electrode are stacked in an order by etching the second planarization unit to expose the first planarization unit, and wherein a side of the second planarization unit is located inwardly of a side of the pixel electrode, bonding a light emitting element by forming an organic pattern layer on the pixel electrode, forming a first partition wall on the first planarization unit to surround the light emitting element, depositing a reflective material layer to cover both the first partition wall and the light emitting element, forming a via layer in a space formed by the first partition wall, and forming a reflective layer by etching a reflective material layer on an upper portion of the light emitting element not covered by the via layer, forming an insulating organic layer having an opening on a top of the light emitting element, forming a downwardly recessed recess on a top surface of the light emitting element by etching the light emitting element with the insulating 1 organic layer as a mask and forming a common electrode in direct contact with the recess of the light emitting element.

Bonding the light emitting element by forming the organic pattern layer on the pixel electrode includes, fully applying an organic pattern material layer on the substrate to cover the first planarization unit and the pixel electrode, arranging the light emitting element to be aligned with the pixel electrode on the organic pattern material layer and bonding the light emitting element by curing the organic pattern material layer.

The first partition wall includes a negative photosensitive material and has an inverted tapered shape which has a width that decreases in a downward direction.

The method further includes forming a capping layer on the common electrode to cover the common electrode, forming a second partition wall on the capping layer to overlap the first partition wall, forming a second reflective layer around a side surface of the second partition wall and forming a wavelength conversion layer in a space formed by the second partition wall.

The method further includes forming a capping layer on the entire surface of the substrate to cover the common electrode, forming a second partition wall on the capping layer to overlap the first partition wall, forming a second reflective layer around a side surface of the second partition wall and forming a wavelength conversion layer in a space formed by the second partition wall.

The method further includes forming an overcoat layer and a color filter layer sequentially located on the wavelength conversion layer and the second partition wall.

According to one or more embodiments, the partition wall and the reflective layer of the light emitting element may be formed in a single process while being electrically separated from each other by adopting an undercut structure.

Additionally, the second semiconductor layer and the common electrode are in direct contact to reduce the contact resistance of the common electrode. This may improve power consumption.

In addition, a wavelength conversion layer may be sufficiently formed to increase light conversion efficiency compared to a single-layer partition wall by forming a multi-layered partition wall.

### BRIEF DESCRIPTION OF THE DRAWINGS

FIG. 1 is a perspective view illustrating a display device according to one or more embodiments.

FIGS. 2 and 3 are plan views illustrating a display device according to one or more embodiments.

FIG. 4 is a circuit diagram illustrating a first sub-pixel of a display panel according to one or more embodiments.

FIG. 5 is a circuit diagram illustrating a first sub-pixel of a display panel according to one or more embodiments.

FIG. 6 is a cross-sectional view schematically illustrating a display device according to one or more embodiments.

FIG. 7 is an enlarged view schematically illustrating the first light-emitting region described with reference to FIG. 6.

FIG. 8 is an enlarged view of a region A of FIG. 7.

FIG. 9 is a view illustrating the corresponding relationship of a plan view and a cross-sectional view of an insulating pattern layer and a light emitting element according to the embodiment described with reference to FIG. 7.

FIG. 10 is an enlarged view of the light emitting element of FIG. 7.

FIG. 11 is an enlarged view schematically illustrating a first light emitting region according to one or more embodiments of FIG. 7.

FIG. 12 is an enlarged view of the light emitting element of FIG. 11.

FIGS. 13-33 are diagrams to illustrate a method of manufacturing a display device according to one or more embodiments.

FIG. 34 is an example diagram schematically showing a virtual reality device including a display device according to one or more embodiments;

FIG. 35 is an example diagram schematically showing a smart device including a display device according to one or more embodiments;

FIG. 36 is a diagram of an example schematically showing a vehicle including a display device according to one or more embodiments.

FIG. 37 is a diagram of an example schematically showing a transparent display device including a display device according to one or more embodiments.

### DETAILED DESCRIPTION

One or more embodiments of the present disclosure will now be described more fully hereinafter with reference to the accompanying drawings. The embodiments may, however, be provided in different forms and should not be construed as limiting. The same reference numbers indicate the same components throughout the present disclosure. In the accompanying figures, the thickness of layers and regions may be exaggerated for clarity.

Some of the parts which are not associated with the description may not be provided in order to describe embodiments of the present disclosure.

It will also be understood that when a layer is referred to as being “on” another layer or substrate, it can be directly on the other layer or substrate, or intervening layers may also be present. In contrast, when an element is referred to as being “directly on” another element, there may be no intervening elements present.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

The spatially relative terms “below,” “beneath,” “lower,” “above,” “upper,” or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

When an element is referred to as being “connected” or “coupled” to another element, the element may be “directly connected” or “directly coupled” to another element, or “electrically connected” or “electrically coupled” to another element with one or more intervening elements interposed therebetween. It will be further understood that when the terms “comprises,” “comprising,” “has,” “have,” “having,” “includes” and/or “including” are used, they may specify the presence of stated features, integers, steps, operations, elements and/or components, but do not preclude the presence or addition of other features, integers, steps, operations, elements, components, and/or any combination thereof.

It will be understood that, although the terms “first,” “second,” “third,” or the like may be used herein to describe various elements, these elements should not be limited by these terms. These terms are used to distinguish one element from another element or for the convenience of description and explanation thereof. For example, when “a first element” is discussed in the description, it may be termed “a second element” or “a third element,” and “a second element” and “a third element” may be termed in a similar manner without departing from the teachings herein.

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within ±30%, 20%, 10%, 5% of the stated value.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.” In the specification and the claims, the phrase “at least one of” is intended to include the meaning of “at least one selected from the group of” for the purpose of its meaning and interpretation. For example, “at least one of A and B” may be understood to mean “A, B, or A and B.”

Unless otherwise defined or implied, all terms used herein (including technical and scientific terms) have the same meaning as commonly understood by those skilled in the art to which the present disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the specification.

Hereinafter, one or more embodiments of the present disclosure will be described in detail with reference to the accompanying drawings.

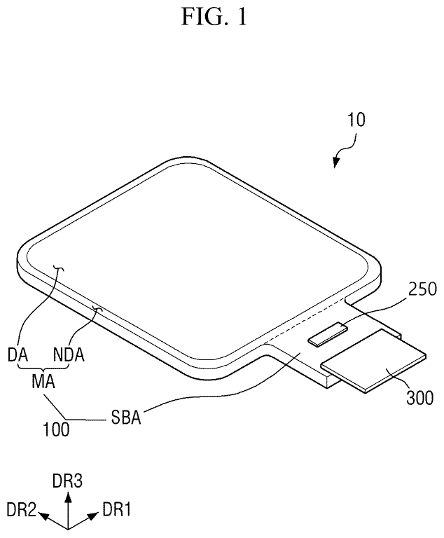

FIG. 1 is a perspective view illustrating a display device according to one or more embodiments.

Referring to FIG. 1, a display device 10 is a device for displaying video and/or still images, and the display device 10 may be used as a display screen of portable electronic devices such as mobile phones, smart phones, tablet personal computers, smart watches, watch phones, mobile communication terminals, electronic notebooks, e-books, portable multimedia players (PMP), navigation, and ultra mobile PCs (UMPC), as well as a variety of products such as televisions, laptops, monitors, billboards, and/or the internet of things (IoT) device.

The display device 10 may be a light-emitting display device, such as an organic light-emitting display device utilizing an organic light-emitting diode, a quantum dot light-emitting display device including a quantum dot light-emitting layer, an inorganic light-emitting display device including an inorganic semiconductor, and a miniaturized light-emitting display device utilizing a micro or nano light emitting diode (micro LED or nano LED). Hereinafter, the description focuses on the fact that the display device 10 is a micro-light emitting display device, but the present disclosure is not limited thereto. On the other hand, the subminiature light-emitting diode is described herein as a micro light-emitting diode for convenience of explanation.

The display device 10 includes a display panel 100, a display driving circuit 250, and a circuit board 300.

The display panel 100 may be formed as a rectangular-shaped plane having a short side in the first direction DR1 and a long side in the second direction DR2 that intersects the first direction DR1. A corner where the short side in the first direction DR1 and the long side in the second direction DR2 meet may be rounded to have a suitable curvature (e.g., a predetermined curvature) or may be formed at a right angle. The planar shape of the display panel 100 is not limited to a rectangle, and may be formed in other polygonal, circular, or oval shapes. The display panel 100 may be formed flat but is not limited thereto. For example, the display panel 100 is formed to include curved portions with a constant curvature or a changing curvature at left and right ends. Additionally, the display panel 100 may be formed to be flexible, such as to be able to be bent, curved, folded, and/or rolled.

The substrate of the display panel 100 may include a main area MA and a sub-area SBA.

The main area MA may include a display area DA that is configured to display an image and a non-display area NDA that is a peripheral area of the display area DA and disposed along one or more edges or a periphery of the display area DA. The display area DA may include a plurality of pixels that display an image. For example, the pixel may include a first sub-pixel that is configured to emit first light, a second sub-pixel that is configured to emit second light, and a third sub-pixel that is configured to emit third light.

The sub-area SBA may protrude from one side of the main area MA in the second direction DR2. Although FIG. 1 illustrates the sub-area SBA being unfolded, the sub-area SBA may be bent, and in this case, may be disposed on the bottom surface of the display panel 100. When the sub-area SBA is bent, it may overlap the main area MA in the third direction DR3, which is the thickness direction of the display panel 100. The display driving circuit 250 may be disposed in the sub-area SBA.

The display driving circuit 250 may generate signals and voltages for driving the display panel 100. The display driving circuit 250 may be formed as an integrated circuit (IC) and attached to the display panel 100 using a chip on glass (COG) method, a chip on plastic (COP) method, or an ultrasonic bonding method but is not limited thereto. For example, the display driving circuit 250 may be attached to the circuit board 300 using a chip on film (COF) method.

The circuit board 300 may be attached to one end of the sub-area SBA of the display panel 100. As such, the circuit board 300 may be electrically connected to the display panel 100 and the display driving circuit 250. The display panel 100 and the display driving circuit 250 may receive digital video data, timing signals, and driving voltages through the circuit board 300. The circuit board 300 may be a flexible printed circuit board (FPCB), a rigid printed circuit board (PCB), or a flexible film such as a chip on film.

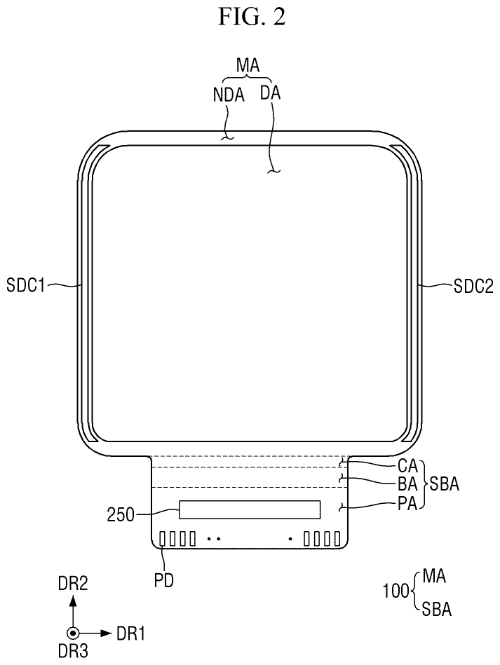

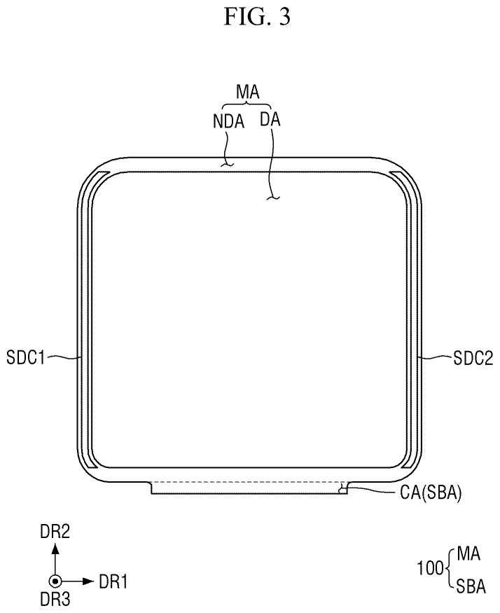

FIGS. 2 and 3 are plan views illustrating a display device according to one or more embodiments. FIG. 2 illustrates that the sub-area SBA is unfolded without being bent. FIG. 3 illustrates that the sub-area SBA is bent.

Referring to FIGS. 2 and 3, the display panel 100 may include the main area MA and the sub-area SBA.

The main area MA may include the display area DA that is configured to display an image and the non-display area NDA that is a peripheral area of the display area DA. The display area DA may occupy most of the main area MA. The display area DA may be placed in the center of the main area MA.

The non-display area NDA may be placed adjacent to the display area DA. The non-display area NDA may be an area outside the display area DA. The non-display area NDA may be arranged to be around (e.g., to surround) the display area DA. The non-display area NDA may be an edge area of the display panel 100.

A first scan driving unit SDC1 and a second scan driving unit SDC2 may be disposed in the non-display area NDA. The first scan driving unit SDC1 is disposed on one side (for example, the left side) of the display panel 100, and the second scan driving unit SDC2 is disposed on the other side (for example, the right side) of the display panel 100. However, it is not limited thereto. Each of the first scan driving unit SDC1 and the second scan driving unit SDC2 may be electrically connected to the display driving circuit 250 through scan fan-out lines. Each of the first scan driving unit SDC1 and the second scan driving unit SDC2 may receive a scan control signal from the display driving circuit 250, generate scan signals according to the scan control signal, and output them to the scan lines.

The sub-area SBA may protrude from one side of the main area MA in the second direction DR2. The length of the sub-area SBA in the second direction DR2 may be smaller than the length of the main area MA in the second direction DR2. The length of the sub-area SBA in the first direction DR1 may be smaller than the length of the main area MA in the first direction DR1 or may be substantially equal to the length of the main area MA in the first direction DR1. The sub-area SBA may be curved and may be disposed at the lower portion of the display panel 100. In this case, the sub-area SBA may overlap the main area MA in the third direction DR3.

The sub-area SBA may include a connection area CA, a pad area PA, and a bending area BA.

The connection area CA is an area protruding from one side of the main area MA in the second direction DR2. One side of the connection area CA may be in contact with the non-display area NDA of the main area MA, and the other side of the connection area CA may be in contact with the bending area BA.

The pad area PA is an area where the pads PD and the display driving circuit 250 are disposed. The display driving circuit 250 may be attached to the driving pads of the pad area PA using a conductive adhesive member such as an anisotropic conductive film. The circuit board 300 may be attached to the pads PD of the pad area PA using a conductive adhesive member such as an anisotropic conductive film. One side of the pad area PA may be in contact with the bending area BA.

The bending area BA is a bendable area. When the bending area BA is bent, the pad area PA may be disposed below the connection area CA and below the main area MA. The bending area BA may be disposed between the connection area CA and the pad area PA. One side of the bending area BA may be in contact with the connection area CA, and the other side of the bending area BA may be in contact with the pad area PA.

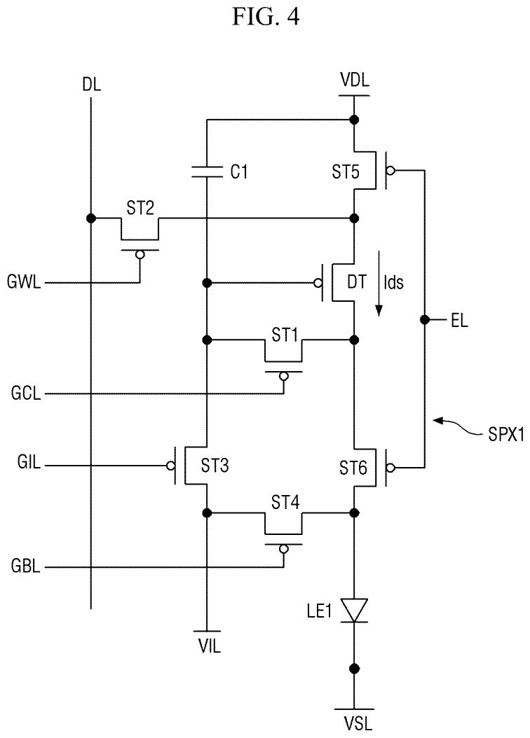

FIG. 4 is a circuit diagram illustrating a first sub-pixel of a display panel according to one or more embodiments.

Referring to FIG. 4, the first sub-pixel SPX1 according to one or more embodiments may be connected to scan lines GWL, GIL, GCL, and GBL, light emitting lines EL, and data lines DL. For example, the first sub-pixel SPX1 may be connected to a write scan line GWL, an initialization scan line GIL, the control scan line GCL, the bias scan line GBL, a light emitting line EL, and the data line DL.

The first sub-pixel SPX1 according to one or more embodiments includes a driving transistor DT, switch elements, a capacitor C1, and a first light emitting element LE1. The switch elements include first to sixth transistors ST1, ST2, ST3, ST4, ST5, and ST6.

The driving transistor DT includes a gate electrode, a first electrode, and a second electrode. The driving transistor DT controls the drain-source current (Ids, hereinafter referred to as “driving current”) flowing between the first electrode and the second electrode according to the data voltage applied to the gate electrode of the driving transistor DT.

The first light emitting element LE1 may be a micro light-emitting diode.

The first light emitting element LE1 is configured to emit light according to the driving current Ids. The amount of light emitted from the first light-emitting element LE1 may be proportional to the driving current Ids. An anode electrode of 1 the first light emitting element LE1 may be connected to the first electrode of the fourth transistor ST4 and the second electrode of the sixth transistor ST6, a cathode electrode may be connected to the second power supply line VSL to which the second power supply voltage is applied.

The capacitor C1 is formed between the gate electrode of the driving transistor DT and the first power supply line VDL to which the first power supply voltage is applied. The first power supply voltage may be at a higher level than the second power supply voltage. One electrode of the capacitor C1 may be connected to the gate electrode of the driving transistor DT, and the other electrode may be connected to the first power supply line VDL.

As shown in FIG. 4, the first to sixth transistors ST1, ST2, ST3, ST4, ST5, and ST6 and the driving transistor DT may all be formed as p-type MOSFET. In this case, the active layer of each of the first to sixth transistors ST1, ST2, ST3, ST4, ST5, and ST6 and the driving transistor DT may be formed of polysilicon or oxide semiconductor.

The gate electrode of the second transistor ST2 may be connected to the write scan line GWL, and the gate electrode of the first transistor ST1 may be connected to the control scan line GCL. The gate electrode of the third transistor ST3 may be connected to the initialization scan line GIL, and the gate electrode of the fourth transistor ST4 may be connected to the bias scan line GBL. Because the first to sixth transistors ST1, ST2, ST3, ST4, ST5, and ST6 are formed as p-type MOSFET, they may be turned on when a scan signal of the gate low voltage and an emission signal are applied to the control scan line GCL, the initialization scan line GIL, the write scan line GWL, the bias scan line GBL, and the light emitting line EL, respectively. One electrode of the third transistor ST3 and one electrode of the fourth transistor ST4 may be connected to an initialization voltage line VIL.

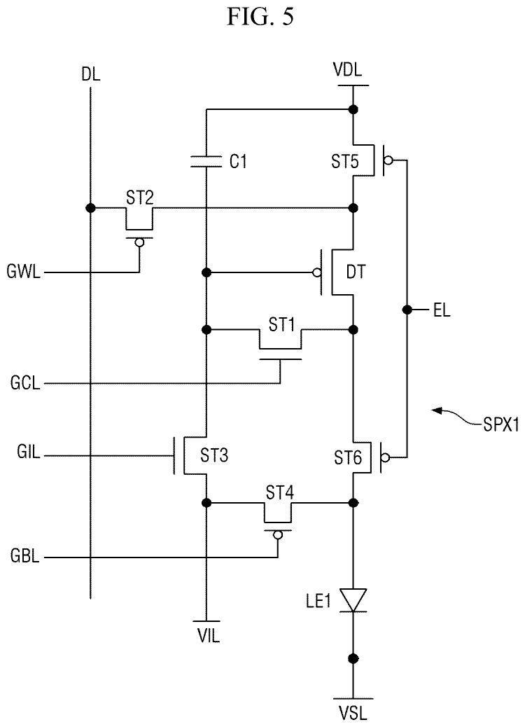

FIG. 5 is a circuit diagram illustrating a first sub-pixel of a display panel according to one or more embodiments.

Referring to FIG. 5, the driving transistor DT, the second transistor ST2, the fourth transistor ST4, the fifth transistor ST5, and the sixth transistor ST6 are formed of p-type MOSFET, and the first transistor ST1 and the third transistor ST3 may be formed as n-type MOSFET. The active layer of each of the driving transistor DT, the second transistor ST2, the fourth transistor ST4, the fifth transistor ST5, and the sixth transistor ST6 formed as the p-type MOSFET may be formed of polysilicon, and the active layer of each of the first transistor ST1 and the third transistor ST3 formed as the n-type MOSFET may be formed of the oxide semiconductor. In this case, transistors formed of polysilicon and transistors formed of oxide semiconductors may be arranged in different layers.

Because the first transistor ST1 and the third transistor ST3 are formed as n-type MOSFET, the first transistor ST1 may be turned on when a control scan signal with a gate high voltage is applied to the control scan line GCL, and the third transistor ST3 may be turned on when an initialization scan signal with a gate high voltage is applied to the initialization scan line GIL. In comparison, the second transistor ST2, the fourth transistor ST4, the fifth transistor ST5, and the sixth transistor ST6 are formed as p-type MOSFET, so they may be turned on when a scan signal with a gate low voltage and an emission signal are applied to the write scan line GWL, the bias scan line GBL, and the light emitting line EL, respectively.

Alternatively, the fourth transistor ST4 in FIG. 4 may be formed of the n-type MOSFET. In this case, the active layer of each fourth transistor ST4 may be formed of the oxide semiconductor. When the fourth transistor ST4 is formed of n-type MOSFET, it may be turned on when a bias scan signal of a gate high voltage is applied to the bias scan line GBL.

For example, the first transistor ST1 is connected between the second electrode and the gate electrode of the driving transistor DT. The second transistor ST2 is connected between the data line DL and the first electrode of the driving transistor DT. The third transistor ST3 is connected between the gate electrode of 1 the driving transistor DT and the initialization voltage line VIL, the fourth transistor ST4 may be connected between the initialization voltage line VIL and the second electrode of the sixth transistor ST6, the fifth transistor ST5 is connected between the first power supply line VDL and the first electrode of the driving transistor DT, and the sixth transistor ST6 is connected between the second electrode of the driving transistor DT and the first light emitting element LE1. The gate electrodes of the fifth and sixth transistors ST5 and ST6 are connected to the light emitting line EL.

Alternatively, in one or more embodiments, the first to sixth transistors ST1, ST2, ST3, ST4, ST5, and ST6 and the driving transistor DT may all be formed as n-type MOSFET.

In one or more embodiments, the circuit diagrams of the second sub-pixel and the third sub-pixel according to one or more embodiments are substantially the same as the circuit diagram of the first sub-pixel SPX1 described in conjunction with FIGS. 4 and 5, so a description thereof will be omitted.

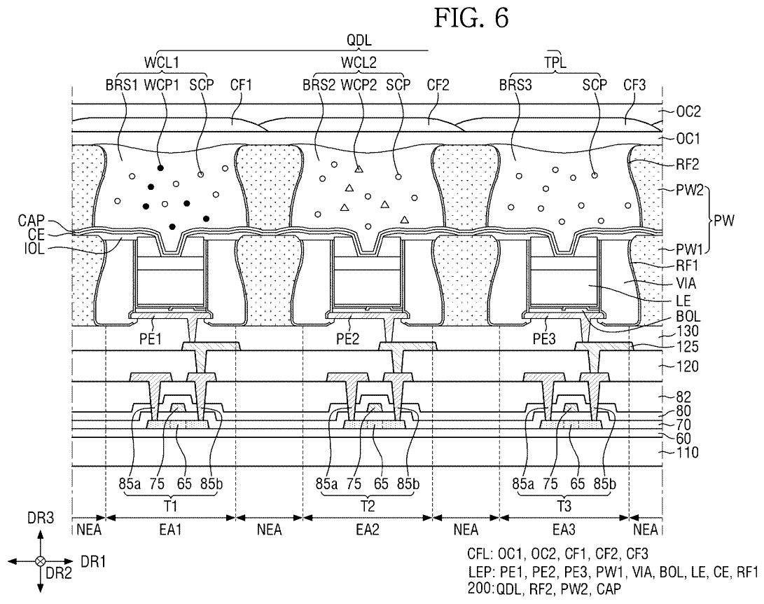

FIG. 6 is a cross-sectional view schematically illustrating a display device according to one or more embodiments.

Referring to FIG. 6, the display device 10 may include a substrate 110, a light emitting element placement unit LEP, a wavelength control unit 200, and a color filter layer CFL.

The substrate 110 may be an insulating substrate. The substrate 110 may include a transparent material. For example, the substrate 110 may include a transparent insulating material such as glass, quartz, etc. The substrate 110 may be a rigid substrate. However, the substrate 110 is not limited thereto and may include plastic such as polyimide and may have flexible characteristics that allow it to be curved, bent, folded, and/or rolled. A plurality of light emitting areas EA1, EA2, and EA3 and a non-emitting area NEA may be defined in the substrate 110.

Switching elements T1, T2, and T3 may be located on the substrate 110. In one or more embodiments, the first switching element T1 may be located in the 1 first light emitting area EA1 of the substrate 110, the second switching element T2 may be located in the second light emitting area EA2, and the third switching element T3 may be located in the third light emitting area EA3. However, it is not limited thereto, and in one or more embodiments, at least one of the first switching element T1, the second switching element T2, and/or the third switching element T3 may be located in the non-emitting area (NEA).

In one or more embodiments, the first switching element T1, the second switching element T2, and the third switching element T3 may each be a thin film transistor (TFT) including amorphous silicon, polysilicon, and/or an oxide semiconductor. Although not shown in the drawing, a plurality of signal lines (e.g., gate lines, data lines, power supply lines, etc.) that transmit signals to each switching element T1, T2, and T3 may be further positioned on the substrate 110.

Each switching element T1, T2, and T3 may include a semiconductor layer 65, a gate electrode 75, a source electrode 85a, and a drain electrode 85b.

Specifically, a buffer layer 60 may be disposed on the substrate 110. The buffer layer 60 may be disposed to cover the entire surface of the substrate 110. The buffer layer 60 includes silicon nitride, silicon oxide, and/or silicon oxynitride, and may be made of a single layer or a double layer thereof.

The semiconductor layer 65 may be disposed on the buffer layer 60. The semiconductor layer 65 may form a channel for each switching element T1, T2, and T3. The semiconductor layer 65 may include amorphous silicon, polycrystalline silicon, and/or an oxide semiconductor. For example, the oxide semiconductor may include a binary compound (ABₓ), a ternary compound (ABₓC_{y}), or a quaternary compound (ABₓC_{y}D_{z}) containing, for example, indium, zinc, gallium, tin, titanium, aluminum, hafnium (Hf), zirconium (Zr), magnesium (Mg), and/or the like. In one or more embodiments, the semiconductor layer 65 may include indium tin zinc oxide (IGZO).

The gate insulating layer 70 may be disposed on the semiconductor layer 65 and the buffer layer 60. The gate insulating layer 70 may include a silicon compound, metal oxide, and/or the like. For example, the gate insulating layer 70 may include a silicon oxide, a silicon nitride, a silicon oxynitride, an aluminum oxide, a tantalum oxide, a hafnium oxide, a zirconium oxide, a titanium oxide, and/or the like. In one or more embodiments, the gate insulating layer 70 may include silicon oxide.

The gate electrode 75 may be disposed on the gate insulating layer 70. The gate electrode 75 may be disposed to overlap the semiconductor layer 65 in the third direction DR3. The gate electrode 75 may include a conductive material. The gate electrode 75 may include a metal oxide such as ITO, IZO, ITZO, In₂O₃, and/or a metal such as copper (Cu), titanium (Ti), aluminum (AI), molybdenum (Mo), tantalum (Ta), calcium (Ca), chromium (Cr), magnesium (Mg), and/or nickel (Ni). For example, the gate electrode 75 may be made of a Cu/Ti double layer in which an upper layer of copper is stacked on a lower layer of titanium but is not limited thereto.

A first interlayer insulating layer 80 and a second interlayer insulating layer 82 may be disposed on the gate electrode 75 and the gate insulating layer 70. The first interlayer insulating layer 80 may be directly disposed on the gate electrode 75, and the second interlayer insulating layer 82 may be directly disposed on the first interlayer insulating layer 80. The first interlayer insulating layer 80 and the second interlayer insulating layer 82 each include an inorganic insulating material such as silicon oxide, silicon nitride, silicon oxynitride, hafnium oxide, aluminum oxide, titanium oxide, tantalum oxide, zinc oxide, and/or the like. However, the present disclosure is not limited thereto, and the second interlayer insulating layer 82 may include an organic insulating material capable of flattening the lower-level difference. In this embodiment, two interlayer insulating layers, the first interlayer insulating layer 80 and the second interlayer insulating layer 82, are illustrated and described, but the present disclosure is not limited thereto, and only one interlayer insulating layer may be disposed.

The source electrode 85a and the drain electrode 85b may be disposed on the second interlayer insulating layer 82. The source electrode 85a and the drain electrode 85b may contact the semiconductor layer 65 through contact holes through the first interlayer insulation layer 80, the second interlayer insulation layer 82, and the gate insulation layer 70, respectively. The source electrode 85a and the drain electrode 85b may include metal oxides such as ITO, IZO, ITZO, In₂O₃, and/or metals such as copper (Cu), titanium (Ti), aluminum (AI), molybdenum (Mo), tantalum (Ta), calcium (Ca), chromium (Cr), magnesium (Mg), and/or nickel (Ni). For example, the source electrode 85a and the drain electrode 85b may be made of a Cu/Ti double layer in which an upper layer of copper is stacked on a lower layer of titanium but is not limited thereto.

A first planarization layer 120 may be disposed on the first switching element T1, the second switching element T2, and the third switching element T3 on the second interlayer insulating layer 82. The first planarization layer 120 may include an organic material. For example, the first planarization layer 120 may include acrylic resin, epoxy resin, imide resin, ester resin, etc. In one or more embodiments, the first planarization layer 120 may include a positive photosensitive material or a negative photosensitive material.

A pixel connection electrode 125 may be disposed on the first planarization layer 120. The pixel connection electrode 125 is disposed to correspond to each of the first switching element T1, the second switching element T2, and the third switching element T3, and may be electrically connected to them. The pixel connection electrode 125 may connect the pixel electrodes PE1, PE2, and PE3 described later to the switching elements T1, T2, and T3 described above. The pixel connection electrode 125 may contact the switching elements T1, T2, and T3 through a contact hole penetrating the first planarization layer 120.

A second planarization layer 130 may be disposed on the first planarization layer 120 and the pixel connection electrode 125. The second planarization layer 130 flattens the lower-level difference and may include the same material as the first planarization layer 120 described above.

The light emitting element placement unit LEP may be disposed on the second planarization layer 130. The light emitting element placement unit LEP may include a plurality of pixel electrodes PE1, PE2, and PE3, an organic pattern layer BOL, a plurality of light emitting elements LE, and a common electrode CE. Hereinafter, the plurality of pixel electrodes PE1, PE2, and PE3, the organic pattern layer BOL, and the plurality of light emitting elements LE are referred to as a light emitting element unit LEU for convenience of explanation.

In addition, the light emitting element placement unit LEP may further include a first partition wall PW1, a first via layer VIA1, an insulating pattern layer (e.g., insulating organic layer) IOL, and a capping layer CPL that compartmentalize each light emitting area EA1, EA2, and EA3.

The plurality of pixel electrodes PE1, PE2, and PE3 may include a first pixel electrode PE1, a second pixel electrode PE2, and a third pixel electrode PE3. The first pixel electrode PE1, the second pixel electrode PE2, and the third pixel electrode PE3 may serve as the first electrode of the light emitting element LE and may be an anode electrode or a cathode electrode. The first pixel electrode PE1 may be located in the first light emitting area EA1, the second pixel electrode PE2 may be located in the second light emitting area EA2, and the third pixel electrode PE3 may be located in the third light emitting area EA3. The light emitting elements LE may be arranged regularly with certain rules (e.g., predetermined rules). For example, the light emitting elements LE may be arranged to be spaced from each other at regular intervals.

In one or more embodiments, the first pixel electrode PE1 may overlap with the first light emitting area EA1, the second pixel electrode PE2 may overlap with the second light emitting area EA2, and the third pixel electrode PE3 may overlap with the third light emitting area EA3.

Each pixel electrode PE1, PE2, and PE3 may be directly connected to the pixel connection electrode 125 through a contact hole penetrating the second planarization layer 130 and may be electrically connected to the respective switching elements T1, T2, and T3 through the pixel connection electrode 125. The first pixel electrode PE1, the second pixel electrode PE2, and the third pixel electrode PE3 may include metal. The metal may include, for example, copper (Cu), titanium (Ti), silver (Ag), magnesium (Mg), aluminum (AI), platinum (Pt), lead (Pd), gold (Au), nickel (Ni), neodymium (Nd), iridium (Ir), chromium (Cr), lithium (Li), calcium (Ca), and/or a mixture thereof. Additionally, the first pixel electrode PE1, the second pixel electrode PE2, and the third pixel electrode PE3 may have a multi-layer structure in which two or more metal layers are stacked. For example, the first pixel electrode PE1, the second pixel electrode PE2, and the third pixel electrode PE3 may have a two-layer structure in which a copper layer is stacked on a titanium layer, but the structure is not limited thereto.

The organic pattern layer BOL and the light emitting element LE may be sequentially disposed on the pixel electrodes PE1, PE2, and PE3. The organic pattern layer BOL may be formed smaller than the width of the plurality of pixel electrodes PE1, PE2, and PE3, exposing at least a portion of the pixel electrodes PE1, PE2, and PE3. In other words, the pixel electrodes PE1, PE2, and PE3 may protrude outwardly from the organic pattern layer BOL.

The organic pattern layer BOL may be arranged in an island pattern shape in each light emitting area EA1, EA2, and EA3. For example, the organic pattern layers BOL disposed in each light emitting area EA1, EA2, and EA3 may be arranged to be spaced from the organic pattern layers BOL disposed in adjacent light emitting areas EA1, EA2, and EA3.

The thickness of a plurality of organic pattern layers BOL may be about 2 μm or less but is not limited thereto.

The plurality of organic pattern layers BOL may include organic materials. The organic material may be, for example, but is not limited to a photosensitive organic insulating material. Also, the organic material may include epoxy-based resin, acrylic-based resin, cadodic resin, and/or imide-based resin.

The plurality of organic pattern layers BOL may be formed through various methods such as an organic imprinting method, an inkjet printing method, an electro-spray method, and/or a stamping method.

In high-resolution display panels, such as the display device 10 according to one or more embodiments, it is difficult to replace the organic pattern layer BOL with an anisotropic conductive film (ACF) because it utilizes a small-sized light emitting element LE.

The light emitting element LE may be disposed on the organic pattern layer BOL. The light emitting element LE may be inorganic light emitting elements made of inorganic materials such as GaN.

The light emitting elements LE may be disposed in each of the first light emitting area EA1, the second light emitting area EA2, and the third light emitting area EA3. The light emitting element LE may be a vertical light emitting diode element extending long in the third direction DR3. That is, the length of the light emitting element LE in the third direction DR3 may be longer than the length in the horizontal direction. The length in the horizontal direction indicates the length in the first direction DR1 or the length in the second direction DR2. For example, the length of the light emitting element LE in the first direction DR1 or the length in the second direction DR2 may be approximately 1 μm to 5 μm but is not limited thereto. Also, the length of the light emitting element LE in the third direction DR3 may be approximately 7 μm to 10 μm. However, the present disclosure is not limited to this, and the length of the light emitting element LE in the third direction DR3 may be equal to or smaller than the length in the horizontal direction.

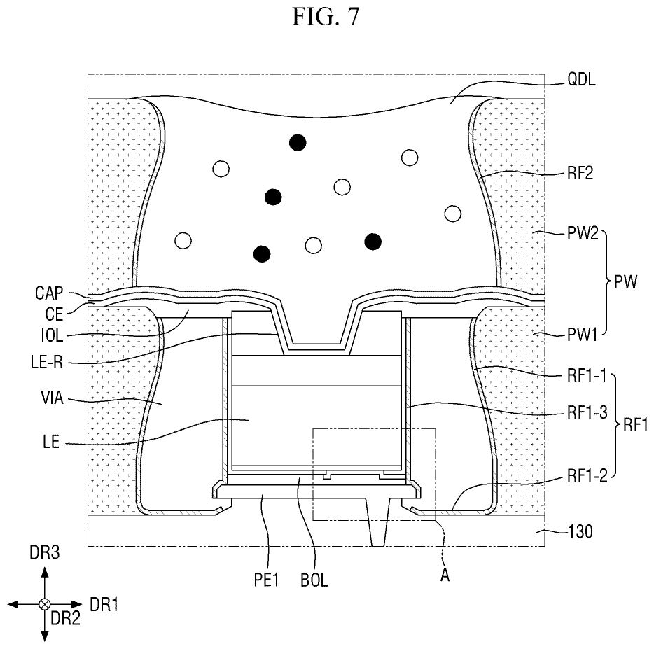

The light emitting element LE may be a micro light emitting diode element. The light emitting element LE includes a recess that is concave from top to bottom. The structure of the light emitting element LE will be described with reference to FIGS. 7 to 9.

The first partition wall PW1 and the via layer VIA that compartmentalize each light emitting area EA1, EA2, and EA3 may be further disposed on the second planarization layer 130.

The first partition wall PW1 may compartmentalize the plurality of light emitting areas EA1, EA2, and EA3. The first partition wall PW1 is arranged to extend in the first direction DR1 and the second direction DR2 and may be formed in a grid-like pattern throughout the display area DA. Additionally, the first partition wall PW1 may not overlap with the plurality of light emitting areas EA1, EA2, and EA3 and may overlap with the non-emitting area NEA.

The first partition wall PW1 may be formed to be around (e.g., surround) the light emitting element LE. The first partition wall PW1 may include a negative photosensitive material and may have a reverse tapered shape.

The first partition wall PW1 may include an organic insulating material such that the first partition wall PW1 may have a large thickness. The organic insulating material may include, for example, epoxy-based resin, acrylic-based resin, cardo-based resin, and/or imide-based resin.

A first reflective layer RF1 may be disposed inside the space formed by the first partition wall PW1 and surrounding the side of the light emitting element unit LEU. The first reflective layer RF1 may be disposed on the inner surface of the first partition wall PW1, the bottom surface of the space formed by the first partition wall PW1, and the side surface of the light emitting element unit LEU. The first reflective layer RF1 may include a metal material with high light reflectance. For example, the first reflective layer RF1 may include aluminum and/or silver, and/or an alloy thereof.

The via layer VIA may be disposed in the space formed by the first partition wall PW1. The via layer VIA may flatten the lower step so that the common electrode CE, which will be described later, may be formed. The height of the via layer VIA may be smaller than the height of the light emitting element LE. The height of the via layer VIA may be the same as the height of the first reflective layer RF1.

The via layer VIA may include, for example, acrylic resin, epoxy resin, phenolic resin, polyamides resin, or polyimides rein, unsaturated polyesters resin, poly phenylenethers resin, polyphenylenesulfides resin, and/or benzocyclobutene (BCB).

The insulating pattern layer IOL may be disposed on the via layer VIA. The insulating pattern layer IOL may be in direct contact with the via layer VIA. The insulating pattern layer IOL may cover a portion of the top surface of

the light emitting element LE and a portion of the top surface of the first partition wall PW1. The insulating pattern layer IOL may prevent connection of first reflective layer RF1 and the common electrode CE (e.g., at the bottom). The insulating pattern layer IOL may be formed of an organic insulating material such as SiOₓ.

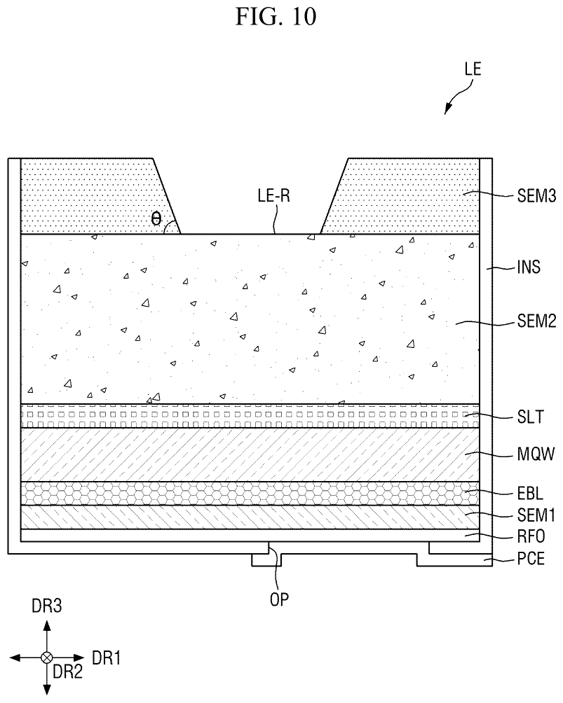

The common electrode CE may be directly disposed on the top surface of the plurality of light emitting elements LE. The common electrode CE may directly contact the second semiconductor layer (SEM2 in FIG. 10) exposed through the opening formed on the top surface of the light emitting element LE. As shown in FIG. 6, the common electrode CE covers the plurality of light emitting elements LE and the insulating pattern layer IOL and may be a common layer disposed in common connection with the plurality of light emitting elements LE.

Because the common electrode CE is disposed entirely on the substrate 110 and applies a common voltage, it may include a material with low resistance. Additionally, the common electrode CE may be formed to be thin to facilitate light 1 transmission. For example, the common electrode CE may include a metal material with low resistance such as aluminum (AI), silver (Ag), copper (Cu), and/or the like, or a metal oxide such as ITO, IZO, ITZO, and/or the like. The thickness of the common electrode CE may be approximately 10 Å to 200 Å but is not limited thereto.

The above-described light emitting elements LE may receive a pixel voltage or anode voltage from each pixel electrode PE1, PE2, and PE3, and may receive a common voltage through the common electrode CE. The light emitting elements LE may emit light with a desired luminance (e.g., a predetermined luminance) depending on a voltage difference between the pixel voltage and the common voltage. In one or more embodiments, by disposing a plurality of light emitting elements LE, that is, inorganic light emitting diodes, on the pixel electrodes PE1, PE2, and PE3, the situations where organic light emitting diodes are vulnerable to external moisture or oxygen may be eliminated and the lifespan and reliability may be improved.

A capping layer CAP may be further disposed on the common electrode CE.

The capping layer CAP serves to cover the light emitting element placement unit LEP disposed below and protect it from moisture or debris. The capping layer CAP may include an inorganic material. For example, the capping layer CAP may include at least one of silicon nitride, aluminum nitride, zirconium nitride, titanium nitride, hafnium nitride, tantalum nitride, silicon oxide, aluminum oxide, titanium oxide, tin oxide, cerium oxide, and/or silicon oxide. In one or more embodiments, the drawing shows that the capping layer CAP is formed as one layer, but the present disclosure is not limited thereto. For example, the capping layer CAP may be formed of multiple layers in which inorganic layers containing at least one of the materials that the capping layer CAP may include are alternately stacked. The thickness of the capping layer CAP may range from 0.05 μm to 2 μm but is not limited thereto.

The wavelength control unit 200 may be disposed on the light emitting element placement unit LEP.

The wavelength control unit 200 may include a second partition wall PW2, a wavelength conversion layer QDL, and a second reflection layer RF2.

The second partition wall PW2 is arranged to extend in the first direction DR1 and the second direction DR2 and may be formed in a grid-like pattern throughout the display area DA. The first partition wall PW1 and the second partition wall PW2 may constitute a partition wall PW. Additionally, the second partition wall PW2 may not overlap with the plurality of light emitting areas EA1, EA2, and EA3 and may overlap with the non-emitting area NEA.

The second partition wall PW2 may be disposed on the first partition wall PW1, overlapping with the first partition wall PW1. The second partition wall PW2 may include a negative photosensitive material and may have a reverse tapered shape. The second partition wall PW2 may serve to provide a space for forming the wavelength conversion layer QDL. The second partition wall PW2 may be thick to provide a space where the wavelength conversion layer QDL is formed. For example, the second partition wall PW2 may include an organic insulating material that is thick. The organic insulating material may include, for example, epoxy-based resin, acrylic-based resin, cardo-based resin, and/or imide-based resin.

In one or more embodiments, the second partition wall PW2 may block the transmission of light in the non-emitting area NEA. The second partition wall PW2 may further include a light blocking material and may include a dye or pigment having light blocking properties. For example, the second partition wall PW2 may be a black matrix. External light incident from the outside of the display device 10 may cause a problem that distorts the color gamut of the wavelength control unit 200. According to one or more embodiments, the second partition wall PW2 including a light blocking material is disposed in the wavelength control unit 200 so that at least a portion of the external light is absorbed by the light blocking material. Therefore, 1 color distortion caused by external light reflection may be reduced. Additionally, the second partition wall PW2 including a light-blocking material may prevent color mixing from occurring due to light intruding between adjacent light-emitting areas, thereby further improving the color reproduction rate.

The second reflective layer RF2 may be disposed on the inner surface of the space formed by the second partition wall PW2. The second reflective layer RF2 may be disposed to not overlap the light emitting areas EA1, EA2, and EA3 and to overlap the non-emitting area NEA. The second reflective layer RF2 is arranged to extend in the first direction DR1 and the second direction DR2 and may be formed in the grid-like pattern throughout the display area DA.

The second reflective layer RF2 may reflect light emitted from the light emitting elements LE upward (e.g., in the third direction DR3). The second reflective layer RF2 may include a metal material with a high light reflectance and may include the same material as the first reflective layer RF1 described above.

The wavelength conversion layer QDL may be disposed in the space formed by the second partition wall PW2. The wavelength conversion layer QDL may convert or shift the peak wavelength of incident light into light of another specific peak wavelength and emit it. The wavelength conversion layer QDL may convert the blue first light emitted from the light emitting element LE into a red second light, a green third light, or transmit the blue first light as is.

The wavelength conversion layer QDL may be disposed in each light emitting area EA1, EA2, and EA3 compartmentalized by the second partition wall PW2 and may be disposed to be spaced from each other. That is, the wavelength conversion layer QDL may be formed in the island pattern spaced from each other. The wavelength conversion layer QDL may be disposed to overlap the first light emitting area EA1, the second light emitting area EA2, and the third light emitting area EA3, respectively. In one or more embodiments, the wavelength conversion layer QDL may completely overlap the corresponding one of the first light emitting area EA1, the second light emitting area EA2, and the third light emitting area EA3.

The wavelength conversion layer QDL includes a first wavelength conversion pattern WCL1 overlapping with the first light emitting area EA1, a second wavelength conversion pattern WCL2 overlapping with the second light emitting area EA2, and a light transmission pattern TPL overlapping the third light emitting area EA3.

The first wavelength conversion pattern WCL1 may be disposed to overlap the first light emitting area EA1. The first wavelength conversion pattern WCL1 may convert or shift the peak wavelength of incident light into light of another specific peak wavelength and emit the light. In one or more embodiments, the first wavelength conversion pattern WCL1 may convert blue first light emitted from the light emitting element LE of the first light emitting area EA1 into second light and emit the second light, which is red light having a single peak wavelength in the range of about 610 nm to about 650 nm.

The first wavelength conversion pattern WCL1 may include a first base resin BRS1, a first wavelength conversion particle WCP1, and a scatterer SCP. The first base resin BRS1 may be the same material as the base resin of the anti-deterioration layer but is not limited thereto. The first base resin BRS1 may include a light-transmitting organic material. For example, the first base resin BRS1 may include epoxy-based resin, acrylic-based resin, cardo-based resin, and/or imide-based resin.

The first wavelength conversion particle WCP1 may convert the first light incident from the light emitting element LE into the second light. For example, the first wavelength conversion particle WCP1 may convert light in the blue wavelength band into light in the red wavelength band. The first wavelength conversion particle WCP1 may be a quantum dot (QD), a quantum rod, a fluorescent material, and/or a phosphorescent material. For example, quantum dots may be particulate materials 1 that emit light of a specific color as electrons transition from the conduction band to the valence band.

The quantum dots may be semiconductor nanocrystalline materials. Depending on its composition and size, the quantum dot may have a specific bandgap to absorb light and emit light with a unique wavelength. Examples of the semiconductor nanocrystals of the quantum dots include Group IV nanocrystals, Group II-VI compound nanocrystals, Group III-V compound nanocrystals, Group IV-VI nanocrystals, and/or combinations thereof.

The Group II-VI compound is a binary compound selected from the group consisting of CdSe, CdTe, ZnS, ZnSe, ZnTe, ZnO, HgS, HgSe, HgTe, MgSe, MgS, and mixtures thereof; a ternary compounds selected from the group consisting of InZnP, AglnS, CulnS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and mixtures thereof; and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and mixtures thereof.

The Group III-V compound is a binary compound selected from the group consisting of GaN, GaP, GaAs, GaSb, AlN, AlP, AIAs, AISb, InN, InP, InAs, InSb, and mixtures thereof; a ternary compound selected from the group consisting of GaNP, GaNAs, GaNSb, GaPAs, GaPSb, AlNP, AlNAs, AlNSb, AlPAS, AlPSb, InGaP, InNP, InAlP, InNAs, InNSb, InPAs, InPSb, and mixtures thereof; and a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and mixtures thereof.

The Group IV-VI compounds may be binary compounds selected from the group consisting of SnS, SnSe, SnTe, PbS, PbSe, PbTe, and mixtures thereof; ternary compounds selected from the group consisting of SnSeS, SnSeTe, SnSTe, PbSeS, PbSeTe, PbSTe, SnPbS, SnPbSe, SnPbTe, and mixtures thereof; and a quaternary compound selected from the group consisting of SnPbSSe, SnPbSeTe, SnPbSTe, and mixtures thereof. The group IV element may be selected from the group consisting of Si, Ge, and mixtures thereof. The Group IV compound may be a binary compound selected from the group consisting of SiC, SiGe, and mixtures thereof.

The binary, ternary, or quaternary compounds may be present in the particle at a uniform concentration or may be present in the same particle with a partially different concentration distribution. The quantum dot may also have a core-shell structure in which one quantum dot surrounds another. The interface of the core and shell may have a concentration gradient where the concentration of an element present in the shell decreases toward the center.

In one or more embodiments, the quantum dot may have a core-shell structure including a core including a nanocrystal as described above and a shell surrounding the core. The shell of the quantum dot may act as a protective layer to prevent chemical denaturation of the core to maintain semiconductor properties and/or as a charging layer to impart electrophoretic properties to the quantum dot. The shell may be monolayer or multilayer. Examples of shells for the quantum dots include oxides of metals or non-metals, semiconductor compounds, and/or combinations thereof.

For example, the oxides of said metals or non-metals may be exemplified by binary compounds such as SiO₂, Al₂O₃, TiO₂, ZnO, MnO, Mn₂O₃, Mn₃O₄, CuO, FeO, Fe₂O₃, Fe₃O₄, CoO, Co₃O₄, NiO, or ternary compounds such as MgAl₂O₄, CoFe₂O₄, NiFe₂O₄, CoMn₂O₄, but the present disclosure is not limited thereto.

In addition, the semiconductor compounds may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AISb, etc., but are not limited thereto.

The second wavelength conversion pattern WCL2 may be disposed to overlap the second light emitting area EA2. The second wavelength conversion pattern WCL2 may emit light by converting or shifting the peak wavelength of incident light into light of another specific peak wavelength. In one or more embodiments, the second wavelength conversion pattern WCL2 converts the blue first light emitted from the light emitting element LE of the second light emitting area EA2 into green third light having a peak wavelength in the range of about 510 nm to 550 nm and emit it.

The second wavelength conversion pattern WCL2 may include a second base resin BRS2 and a second wavelength conversion particle WCP2 and the scatterer SCP dispersed in the second base resin BRS2.

The second base resin BRS2 may be made of a material with high light transmittance, may be made of the same material as the first base resin BRS1, or may include at least one of the materials exemplified as their constituent materials.

The second wavelength conversion particle WCP2 may convert or shift the peak wavelength of incident light to another specific peak wavelength. In one or more embodiments, the second wavelength conversion particle WCP2 may convert the blue first light provided from the light emitting element LE into green third light having a peak wavelength in the range of about 510 nm to 550 nm and emit it. Examples of the second wavelength conversion particle WCP2 include quantum dots, quantum rods, and/or phosphors. A more specific description of the second wavelength conversion particle WCP2 is substantially the same as or similar to that described above in the description of the first wavelength conversion particle WCP1 and will be omitted.

The light transmission pattern TPL may be arranged to overlap the third light emitting area EA3. The light transmission pattern TPL may transmit incident light. The light transmission pattern TPL may directly transmit the blue first light emitted from the light emitting element LE disposed in the third light emitting area EA3. The light transmission pattern TPL may include a third base resin BRS3 and the scatterer SCP dispersed in the third base resin BRS3. Because the third base resin BRS3 is substantially the same as or similar to the above-described first base resin BRS1, description thereof will be omitted.

In one or more embodiments, the color filter layer CFL may be disposed on the wavelength control unit 200. The color filter layer CFL may include a first overcoat layer OC1, a first color filter CF1, a second color filter CF2, a third color filter CF3, and a second overcoat layer OC2.

The first overcoat layer OC1 may be disposed on the wavelength control unit 200. The first overcoat layer OC1 may be directly disposed on the wavelength conversion layer QDL of the wavelength control unit 200. The first overcoat layer OC1 may be disposed entirely over the display area DA and may have a flat surface. The first overcoat layer OC1 may flatten the step formed by the lower wavelength control unit 200 to facilitate the formation of the color filter layer CFL.

The first overcoat layer OC1 may include a light-transmitting organic material. For example, the first overcoat layer OC1 may include epoxy resin, acrylic resin, cardo resin, and/or imide resin.

The first color filter CF1, the second color filter CF2, and the third color filter CF3 may be disposed on the first overcoat layer OC1. The first color filter CF1 may be disposed in the first light emitting area EA1, the second color filter CF2 may be disposed in the second light emitting area EA2, and the third color filter CF3 may be disposed in the third light emitting area EA3.

The first color filter CF1, the second color filter CF2, and the third color filter CF3 may include a colorant such as the dye or pigment that absorbs wavelengths other than the corresponding color wavelength. The first color filter CF1 may selectively transmit the second light (e.g., red light) and block or absorb the first light (e.g., blue light) and the third light (e.g., green light). The second color filter CF2 may selectively transmit the third light (e.g., green light) and block or absorb the first light (e.g., blue light) and the second light (e.g., red light). The third color filter CF3 may selectively transmit the first light (e.g., blue light) and block or absorb the second light (e.g., red light) and the third light (e.g., green light). For example, the first color filter CF1 may be a red color filter, the second color filter CF2 may be a green color filter, and the third color filter CF3 may be a blue color filter.

In one or more embodiments, the light incident on the first color filter CF1 may be light converted to second light in the first wavelength conversion pattern WCL1, the light incident on the second color filter CF2 may be light converted to third light in the second wavelength conversion pattern WCL2, and the light incident on the third color filter CF3 may be first light transmitted through the light transmission pattern TPL. As a result, the second light transmitted through the first color filter CF1, the third light transmitted through the second color filter CF2, and the first light transmitted through the third color filter CF3 may be emitted to the top of the substrate 110 to achieve full color.

The first color filter CF1, the second color filter CF2, and the third color filter CF3 may absorb a portion of the light entering from the outside of the display device 10 to reduce the reflected light caused by external light. Accordingly, the first color filter CF1, the second color filter CF2, and the third color filter CF3 may prevent color distortion due to reflection of external light.

The plane area of the first color filter CF1, the second color filter CF2, and the third color filter CF3 may be larger than the planar area of the corresponding one of the plurality of light emitting areas EA1, EA2, and EA3. For example, the plane area of the first color filter CF1 may be larger than the planar area of the first light emitting area EA1. The plane area of the second color filter CF2 may be larger than the planar area of the second light emitting area EA2. The plane area of the third color filter CF3 may be larger than the planar area of the third light emitting area EA3. However, it is not limited thereto, and the planar area of each of the first color filter CF1, the second color filter CF2, and the third color filter CF3 may be equal to the planar area of each of the plurality of light emitting areas EA1, EA2, and EA3.

The second overcoat layer OC2 may be disposed on the first color filter CF1, the second color filter CF2, and the third color filter CF3. The second overcoat layer OC2 may be directly disposed on the first color filter CF1, the second color filter CF2, and the third color filter CF3. The second overcoat layer OC2 may be disposed entirely in the display area DA and may have a flat surface. The second overcoat layer OC2 may flatten the step formed by the lower first color filter CF1, the second color filter CF2, and the third color filter CF3. The second overcoat layer OC2 may include a light-transmitting organic material and may be substantially the same as or similar to the first overcoat layer OC1 described above.

As described above, the display device 10 according to one or more embodiments may improve the light emission efficiency of the light emitting element LE by forming the first reflective layer RF1 on the side of the first partition wall PW1 and on the substrate 110 in a region not overlapping with the light emitting element LE between the first partition wall PW1 and the adjacent first partition wall PW1.

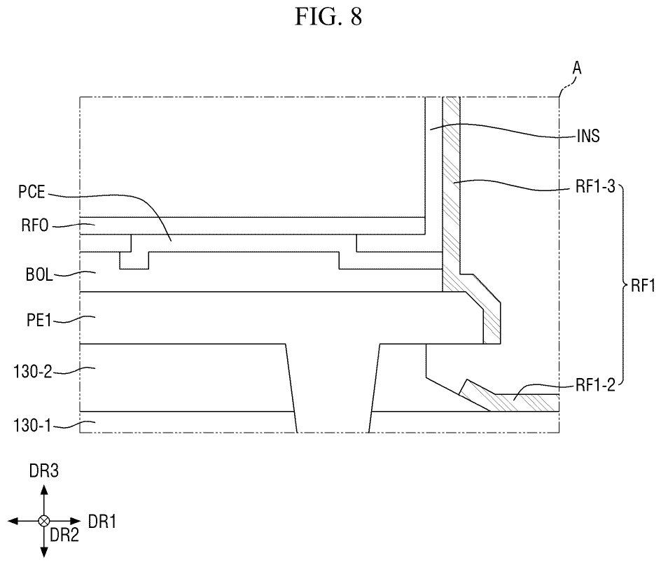

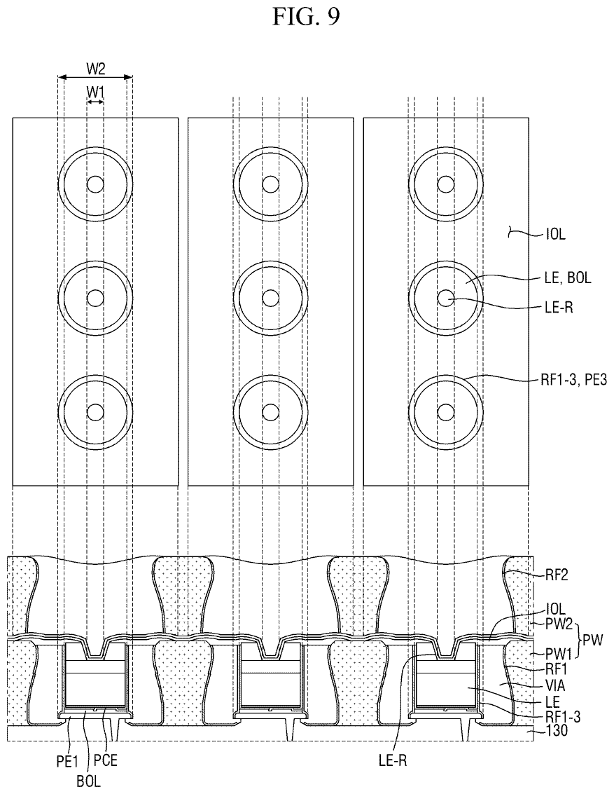

FIG. 7 is an enlarged view schematically illustrating the first light-emitting region described with reference to FIG. 6. FIG. 8 is an enlarged view of region A of FIG. 7. FIG. 9 is a view illustrating the corresponding relationship of a plan view and a cross-sectional view of an insulating pattern layer and a light emitting element according to the embodiment described with reference to FIG. 7. FIG. 10 is an enlarged view of the light emitting element of FIG. 7.

Referring to FIGS. 7 to 9, the second planarization layer 130 may have an undercut structure in a portion overlapping the pixel electrodes PE1, PE2, and PE3. For example, the second planarization layer 130 may include a first planarization unit 130-1 disposed on the substrate (110 in FIG. 6) and a second planarization unit 130-2 disposed on the first planarization unit 130-1. The second planarization unit 130-2 overlaps the pixel electrodes PE1, PE2, and PE3 in the third direction DR3. The first planarization unit 130-1 may be disposed on the front surface of the substrate 110, while the second planarization unit 130-2 may be disposed in an area overlapping the pixel electrodes PE1, PE2, and PE3. The second planarization layer 130 has an undercut shape in which the side surface of the second planarization unit 130-2 is located inwardly from the sides of the pixel electrodes PE1, PE2, and PE3.

An organic pattern layer BOL is disposed on the pixel electrodes PE1, PE2, and PE3 and may cover a portion of the pixel electrodes PE1, PE2, and PE3. The organic pattern layer BOL may expose at least a portion of the pixel electrodes PE1, PE2, and PE3.

The organic pattern layer BOL may be disposed to overlap the light emitting element LE. The light emitting element LE may be disposed on the organic pattern layer BOL. The side surface of the organic pattern layer BOL may be aligned with the side surface of the light emitting element LE.

The first partition wall PW1 may be formed to be higher than the height of the light emitting element LE. The height of the first partition wall PW1 may be about 6 μm to 8 μm but is not limited thereto. The first partition wall PW1 may be formed to have the same height as the light emitting element LE. The second partition wall PW2 may be formed to be equal to the height of the first partition wall PW1 or shorter in height than the first partition wall PW1. The height of the second partition wall PW2 may be about 4 μm to 6 μm but is not limited thereto. The total height of the first partition wall PW1 and the second partition wall PW2 may be about 10 to 14 μm but is not limited thereto.

The via layer VIA may be disposed in the space formed by the first partition wall PW1. The via layer VIA may be disposed on a second reflective unit RF1-2 disposed on the first planarization unit 130-1. The height of the via layer VIA may be equal to or lower than the height of the light emitting element LE. The height of the via layer VIA and the height of the light emitting element LE may refer to a distance from the top surface of the second reflective unit RF1-2 in the third direction DR3.

The first reflective layer RF1 may be arranged to be around (e.g., to surround) the inner wall of the space formed by the first partition wall PW1, and the second reflective layer RF2 may be arranged to be around (e.g., surround) the inner wall of the space formed by the second partition wall PW2.

The first reflective layer RF1 may include a first reflective unit RF1-1 may be around (e.g., surrounding) the side of the first partition wall PW1, and a second reflective unit RF1-2 disposed on a bottom surface between the first partition wall PW1 and the light emitting element LE, and a third reflective unit RF1-3 which is may be around (e.g., surrounding) the light emitting element LE. The second reflective unit RF1-2 is arranged to extend from the first reflective unit RF1-1 but is cut off from (e.g., separated or spaced from) the third reflective unit RF1-3 by the undercut shape of the second planarization unit 130-2. In other words, the inside of the space formed by the first partition wall PW1 may be covered by the first reflective layer RF1 except for the top side.

The light emitting element LE may include a recess LE-R on the top surface and a pad connection electrode PCE on bottom surface (e.g., FIGS. 9-10). The recess LE-R is disposed on the top surface of the light emitting element LE and has a regular tapered shape. The width of the recess LE-R may be 40% or more of the width of the light emitting element LE. For example, when the width of the light emitting element LE is about 10 μm, the width of the recess LE-R may be about 4 μm but is not limited thereto. The width of the recess LE-R may mean the width of the narrowest portion of the width of the recess LE-R. For example, when the recess LE-R is disposed on the top surface of the second semiconductor layer (SEM2 in FIG. 10) of the light emitting element LE, the width of the recess LE-R may mean the width of the recess LE-R on the second semiconductor layer (SEM2 in FIG. 10). The pad connection electrode PCE may be disposed on the bottom

surface of the light emitting element LE. The pad connection electrode PCE is disposed on the bottom surface of the light emitting element LE and may be disposed at a width equal to or less than the width of the light emitting element LE. One side of the pad connection electrode PCE may be aligned with one side of the light emitting element LE. The pad connection electrode PCE may be disposed in an overlapping region with the pixel electrodes PE1, PE2, and PE3. One side of the pad connection electrode PCE may be aligned with one side of the organic pattern layer BOL. The pad connection electrode PCE may be formed of one or more of molybdenum (Mo), aluminum (AI), chromium (Cr), gold (Au), titanium (Ti), nickel (Ni), neodymium (Nd), and/or copper (Cu).

One side of the pad connection electrode PCE may be directly connected to the third reflective unit RF1-3 to be around (e.g., surrounding) the light emitting element LE.

Because the third reflective unit RF1-3 is in direct contact with the pixel electrodes PE1, PE2, and PE3, the light emitting element LE is electrically connected to the pixel electrodes PE1, PE2, and PE3 through the pad connection electrode PCE and the third reflective unit RF1-3. Accordingly, the light emitting element LE may be provided with a pixel voltage or an anode voltage.

The third reflective unit RF1-3 is disposed on the side of the light emitting element LE, and the third reflective unit RF1-3 is disposed on the sides of the pixel electrodes PE1, PE2, and PE3 with their other ends contacting an insulating organic layer IOL. The third reflective unit RF1-3 may be insulated from the common electrode CE by the insulating organic layer IOL.

As shown in FIG. 9, the insulating organic layer IOL may be disposed to correspond to and overlap each of the light emitting areas EA1, EA2, and EA3. The insulating organic layer IOL may be arranged to be spaced from each other in the different light emitting areas EA1, EA2, and EA3. The insulating organic layer IOL may cover the top surface of the via layer VIA and may cover the top surface except for the recess LE-R of the light emitting element LE (that is, an end of the insulating organic layer IOL may be in contact with an end of the recess LE-R). Additionally, the insulating organic layer IOL may cover a portion of the first partition wall PW1.

The insulating organic layer IOL may include a plurality of holes disposed in regions corresponding to the recesses LE-R of the light emitting element LE. That is, the insulating organic layer IOL may not be formed in the regions corresponding to the recess LE-R of the light emitting element LE. When the top surface of the light emitting element LE is circular, the recess LE-R may also be formed to be circular. In this case, the light emitting element LE and the recess LE-R may be concentric circles.

In one or more embodiments, the planar shape of the pixel electrodes PE1, PE2, and PE3 may be similar to the planar shape of the third reflective unit RF1-3 described above. The planar shape of the light emitting element LE may be similar to the planar shape of the organic pattern layer BOL described above.

The common electrode CE may be directly disposed on the top surface of the plurality of light emitting elements LE. The common electrode CE may contact the recess LE-R formed on the top surface of the light emitting element LE. That is, the common electrode CE may be disposed to extend along the side of the recess LE-R. The light emitting element LE may expose the second semiconductor layer SEM2 by the recess LE-R formed to penetrate the third semiconductor layer SEM3. In this case, the common electrode CE may directly contact the second semiconductor layer SEM2 exposed by the recess LE-R. The common electrode CE may directly contact the second semiconductor layer SEM2 of each light emitting element LE, so that a common voltage may be applied to each light emitting element LE. In one or more embodiments, the common electrode CE does not directly contact a portion of the light emitting element LE except for the portion exposed by the recess LE-R due to the insulating pattern layer IOL except for the recess LE-R, so short circuit of the light emitting element LE may be prevented.

The capping layer CAP may be disposed on the common electrode CE to cover the common electrode CE. The capping layer CAP may be omitted.

The wavelength conversion layer QDL may be disposed in the space formed by the second partition wall PW2.

As shown in FIG. 10, the light emitting element LE includes a first semiconductor layer SEM1, an electron blocking layer EBL, an active layer MQW, a superlattice layer SLT, a second semiconductor layer SEM2, and a third semiconductor layer SEM3 arranged along the third direction DR3. The first semiconductor layer SEM1, the electron blocking layer EBL, the active layer MQW, the superlattice layer SLT, the second semiconductor layer SEM2, and the third semiconductor layer SEM3 may be stacked sequentially along the third direction DR3.

The first semiconductor layer SEM1 may be doped with a first conductivity type dopant, such as Mg, Zn, Ca, Sr, and/or Ba. For example, the first semiconductor layer SEM1 may be p-GaN doped with p-type Mg. The thickness of the first semiconductor layer SEM1 may be approximately 30 to 200 nm.

The electron blocking layer EBL may be disposed on the first semiconductor layer SEM1. The electron blocking layer EBL may be a layer for suppressing or preventing too many electrons from flowing into the active layer MQW. For example, the electron blocking layer EBL may be p-AlGaN doped with p-type Mg. A thickness of the electron blocking layer EBL may be approximately 10 nm to 50 nm. The electron blocking layer EBL may be omitted.

The active layer MQW may be disposed on the electron blocking layer EBL. The active layer MQW may emit light by recombining electron-hole pairs according to electrical signals applied through the first semiconductor layer SEM1 and the second semiconductor layer SEM2. The active layer MQW may emit first light having a central wavelength range of 450 nm to 495 nm, that is, light in the blue wavelength band.

The active layer MQW may include a material having a single or multi-quantum well structure. When the active layer MQW includes a material having a multi-quantum well structure, it may have a structure in which a plurality of well layers and barrier layers are alternately stacked. In this case, the well layer may be formed of InGaN, and the barrier layer may be formed of GaN and/or AlGaN but is not limited thereto. The thickness of the well layer may be approximately 1 to 4 nm, and the thickness of the barrier layer may be approximately 3 nm to 10 nm.

Alternatively, the active layer MQW may have a structure in which semiconductor materials having a high energy band gap and semiconductor materials having a low energy band gap are alternately stacked with each other, may include other Group III to V semiconductor materials according to the wavelength range of emitted light. The light emitted from the active layer MQW is not limited to the first light (e.g., light in the blue wavelength band) and may emit second light (e.g., light in the red wavelength band) or third light (e.g., light in the green wavelength band) in some cases. The thickness of the active layer MQW may be approximately 10 nm to 25 nm.

The superlattice layer SLT may be disposed on the active layer MQW. The superlattice layer SLT may be a layer for relieving stress between the second semiconductor layer SEM2 and the active layer MQW. For example, the superlattice layer SLT may be formed of InGaN and/or GaN. A thickness of the superlattice layer SLT may be approximately 50 to 200 nm. The superlattice layer SLT may be omitted.

The second semiconductor layer SEM2 may be disposed on the superlattice layer SLT. The second semiconductor layer SEM2 may be doped with a second conductivity type dopant such as Si, Se, Ge, and/or Sn. For example, the second semiconductor layer SEM2 may be n-GaN doped with n-type Si. A thickness of the second semiconductor layer SEM2 may be approximately 500 nm to 1 μm.

The third semiconductor layer SEM3 may include the same material as the second semiconductor layer SEM2 but may be a material that is not doped with an n-type or p-type dopant. In one or more embodiments, the third semiconductor layer SEM3 may be at least one of undoped InAlGaN, GaN, AlGaN, InGaN, AlN, and/or InN, but is not limited thereto.

The third semiconductor layer SEM3 has a downwardly concave recess LE-R. The recess LE-R may penetrate the third semiconductor layer SEM3 and 1 expose one surface of the second semiconductor layer SEM2. The recess LE-R may have the regular tapered shape, and the inclination angle θ of the inclined surface may be an acute angle.

In addition, the light emitting element LE may further include an element reflective layer RFO, an insulating layer INS, and a pad connection electrode PCE.

The element reflective layer RFO may be disposed on the bottom surface of the first semiconductor layer SEM1, and interposed between the pad connection electrode PCE and the first semiconductor layer SEM1.

The element reflective layer RFO may be in direct contact with the first semiconductor layer SEM1. The element reflective layer RFO reflects light emitted from the active layer MQW of the light emitting element LE toward the display surface (e.g., in the third direction DR3) to improve the light emission efficiency of the light emitting element LE. The element reflective layer RFO may include a metal material that is conductive and has a high light reflectance. For example, the element reflective layer RFO may include aluminum (Al) and/or silver (Ag) and/or may be an alloy thereof.

The insulating layer INS may be disposed on a side surface (e.g., around a peripheral or circumferential outer surface) of each light emitting element LE and a bottom surface of the light emitting element LE. The insulating layer INS may not be disposed on the top surface of each light emitting element LE. The insulating layer INS may be disposed on the bottom surface of the element reflective layer RFO. The insulating layer INS may include an opening OP. The insulating layer INS may expose the element reflective layer RFO through the opening OP.

The pad connection electrode PCE may be disposed on the bottom surface of the light emitting element LE on the insulating layer INS. The pad connection electrode PCE is disposed to cover the opening OP of the insulating layer INS, and may directly contact the element reflective layer RFO exposed through the opening OP. Accordingly, the pad connection electrode PCE and the element reflective layer RFO may be electrically connected. One side of the pad connection electrode PCE may be aligned with one side of the light emitting element LE. One side of the pad connection electrode PCE may be disposed on a straight line with one side of the light emitting element LE. The insulating layer INS may be formed of an inorganic film such as silicon oxide (SiO₂), aluminum oxide (Al₂O₃), and/or hafnium oxide (HfOₓ) but is not limited thereto.

One side of the pad connection electrode PCE may be in direct contact with the third reflective unit RF1-3, as described in FIGS. 7 and 8. Accordingly, the pad connection electrode PCE may be electrically connected to the pixel electrode PE1 along the third reflective unit RF1-3.

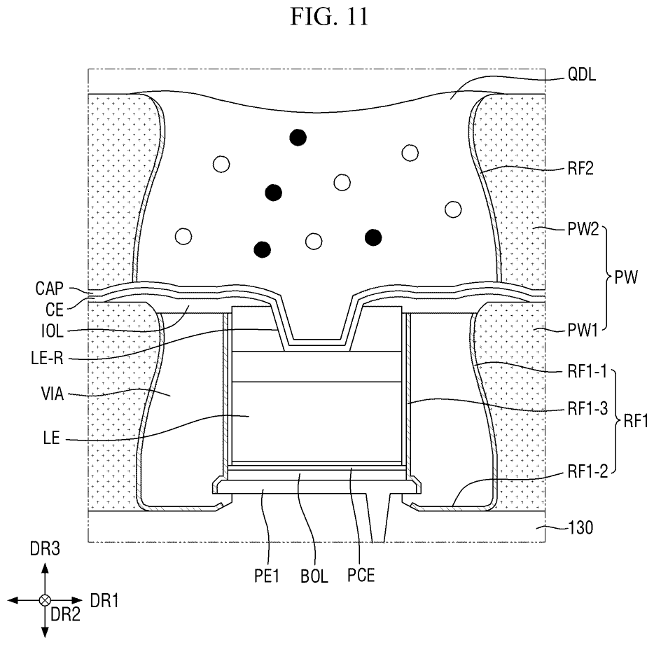

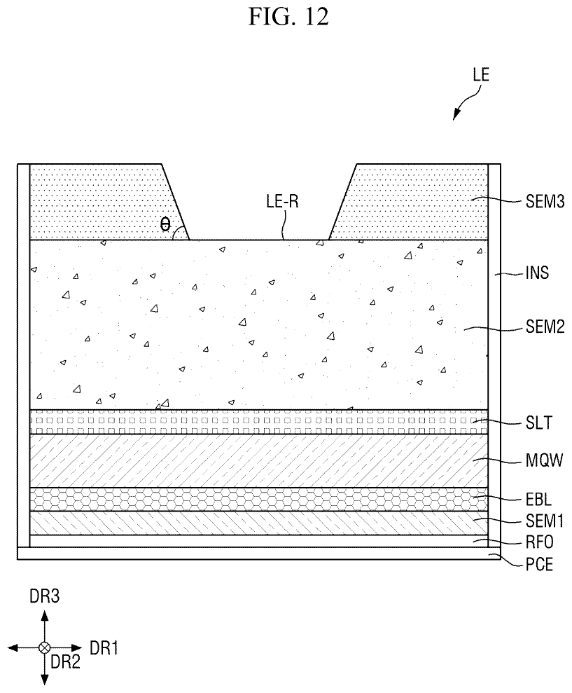

FIG. 11 is an enlarged view schematically illustrating a first light emitting region according to one or more embodiments of FIG. 7. FIG. 12 is an enlarged view of the light emitting element of FIG. 11.

Referring to FIGS. 11 and 12, the insulating layer INS of the light emitting element LE differs from the embodiments of FIGS. 6 to 10 above in that the insulating layer INS is not disposed on the bottom side of the light emitting element LE, and the pad connection electrode PCE is disposed on the entire bottom side of the light emitting element LE. Hereinafter, descriptions overlapping with the above-described embodiment will be omitted and differences will be described.

As shown in FIG. 12, the light emitting element LE includes the first semiconductor layer SEM1, the electron blocking layer EBL, the active layer MQW, the superlattice layer SLT, the second semiconductor layer SEM2, and the third semiconductor layer SEM3 arranged along the third direction DR3. The first semiconductor layer SEM1, the electron blocking layer EBL, the active layer MQW, the superlattice layer SLT, the second semiconductor layer SEM2, and the third semiconductor layer SEM3 may be stacked sequentially along the third direction DR3.

In addition, the light emitting element LE may further include the element reflective layer RFO, the insulating layer INS, and the pad connection electrode PCE.

The element reflective layer RFO may be disposed on the bottom surface of the first semiconductor layer SEM1.

The insulating layer INS may be disposed only on the side (e.g., around a peripheral or circumferential outer surface) of each light emitting element LE. The insulating layer INS may not be disposed on the bottom surface of the light emitting element LE.

Therefore, the pad connection electrode PCE may be disposed on one side of the element reflective layer RFO.

The pad connection electrode PCE may be disposed on the entire surface of the light emitting element LE. That is, the pad connection electrode PCE may be disposed on the entire surface of the element reflective layer RFO. In this way, when the pad connection electrode PCE is disposed on the entire bottom surface of the element reflective layer RFO, the contact surface of the pad connection electrode PCE with the third reflective unit RF1-3 may be further increased.

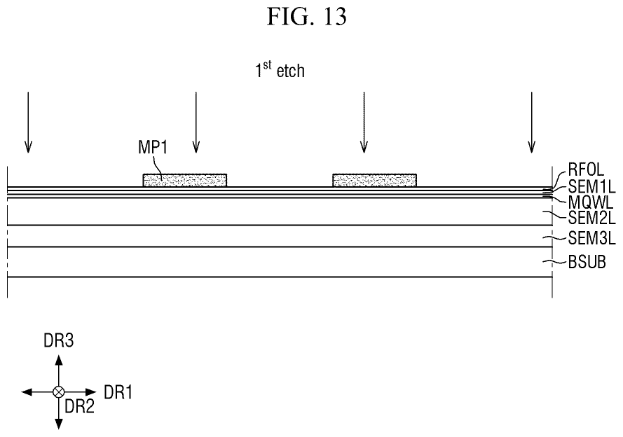

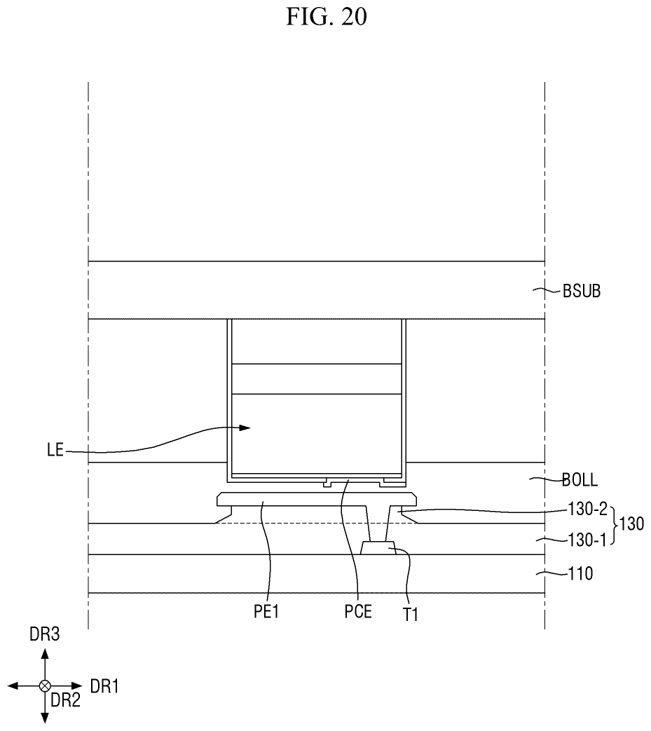

FIGS. 13 to 33 are diagrams to illustrate a method of manufacturing a display device according to one or more embodiments.

FIGS. 13 to 33 illustrate the structure of each layer of the display device 10 in the order of formation, respectively in cross-sectional view. FIGS. 13 to 33 illustrate the manufacturing process of the light emitting element placement unit LEP, which may be roughly corresponding to the cross-sectional views of FIGS. 6 to 8 and FIG. 10, respectively. Also, the first light emitting area EA1 of the display device 10 is highlighted below.

Referring to FIGS. 13 to 16, a plurality of light emitting elements LE are formed on the base substrate BSUB.

Specifically, the base substrate BSUB is prepared. The base substrate BSUB may be a sapphire substrate Al₂O₃ or a silicon wafer including silicon. However, it is not limited thereto, and in one or more embodiments, a case where the base substrate BSUB is a sapphire substrate will be described as an example.

A plurality of semiconductor material layers SEM3L, SEM2L, MQWL, and SEM1L are formed on the base substrate BSUB. The plurality of semiconductor material layers SEM3L, SEM2L, MQWL, and SEM1L grown by the epitaxial method may be formed by growing a seed crystal. Methods for forming semiconductor material layers SEM3L, SEM2L, MQWL, and SEM1L include electron beam deposition, physical vapor deposition (PVD), chemical vapor deposition (CVD), and plasma laser deposition (PLD), dual-type thermal evaporation, sputtering, metal organic chemical vapor deposition (MOCVD), and the like, and preferably formed by metal organic chemical vapor deposition (MOCVD). However, it is not limited thereto.

A precursor material for forming the plurality of semiconductor material layers SEM3L, SEM2L, MQWL, and SEM1L is not particularly limited within the range that may be conventionally selected for forming the subject material. In one example, the precursor material may be a metal precursor including an alkyl group such as a methyl or ethyl group. For example, it may be a compound such as trimethyl gallium (Ga(CH₃)₃), trimethyl aluminum (Al(CH₃)₃), triethyl phosphate ((C₂H₅)₃PO₄) but are not limited thereto.

Specifically, a third semiconductor material layer SEM3L is formed on the base substrate BSUB. While the drawings illustrate the third semiconductor material layer SEM3L being stacked as one layer, it is not limited to this, and a plurality of layers may be formed. The third semiconductor material layer SEM3L may be disposed to reduce a lattice constant difference between a second semiconductor material layer SEM2L and the base substrate BSUB. For example, the third semiconductor material layer SEM3L may include an undoped semiconductor, which may be an n-type or p-type undoped material. In an embodiment, the third semiconductor material layer SEM3L may be at least one of undoped InAlGaN, GaN, AlGaN, InGaN, AlN, and InN but is not limited thereto.

The second semiconductor material layer SEM2L, the active material layer MQWL, and the first semiconductor material layer SEM1L are sequentially formed on the third semiconductor material layer SEM3L by using the above-described method. Next, an element reflective material layer RFOL is formed on the plurality of

semiconductor material layers SEM3L, SEM2L, MQWL, and SEM1L. The element reflective material layer RFOL may be formed to cover all the plurality of semiconductor material layers SEM3L, SEM2L, MQWL, and SEM1L. The element reflective material layer RFOL may include aluminum (Al) and/or silver (Ag) and/or may be an alloy thereof.

Then, a plurality of semiconductor material layers SEM3L, SEM2L, MQWL, and SEM1L and the element reflective material layers RFOL are etched.

Specifically, a plurality of first mask patterns MP1 are formed on the element reflective material layer RFOL. The first mask pattern MP1 may be a hard mask including an inorganic material or a photoresist mask including an organic material. The first mask pattern MP1 prevents the lower plurality of semiconductor material layers SEM3L, SEM2L, MQWL, and SEM1L and the element reflective material layer RFOL from being etched. Next, a portion of the plurality of semiconductor material layers SEM3L, SEM2L, MQWL, SEM1L and the element reflective material layer RFOL are etched (1^{st} etch) using the plurality of first mask patterns MP1 as a mask.

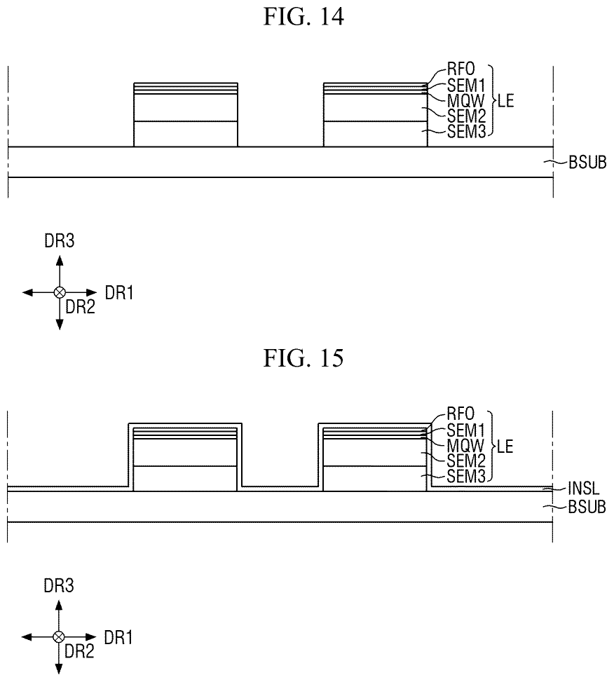

As shown in FIG. 14, on the base substrate BSUB, the plurality of semiconductor material layers SEM3L, SEM2L, MQWL, and SEM1L and the element reflective material layer RFOL that are non-overlapping with the first mask pattern MP1 are etched and removed, and the portions that are not etched overlapping with the first mask pattern MP1 may be formed into the plurality of light emitting elements LE.

The plurality of semiconductor material layers SEM3L, SEM2L, MQWL, and SEM1L and the element reflective material layers RFOL may be etched by conventional methods. For example, the process of etching the plurality of semiconductor material layers SEM3L, SEM2L, MQWL, and SEM1L and the element reflective material layers RFOL may be performed by dry etching, wet etching, reactive ion etching (RIE), deep reactive ion etching (DRIE), inductively coupled plasma reactive ion etching (ICP-RIE), and the like. In the case of dry etching methods, anisotropic etching is possible, which may be suitable for vertical etching. When utilizing the etching method described above, the etchant may be Cl₂ or O₂. However, it is not limited thereto.

The plurality of semiconductor material layers SEM3L, SEM2L, MQWL, and SEM1L and the element reflective material layers RFOL overlapping the first mask pattern MP1 are not etched but are formed into the plurality of light emitting elements LE. Thus, the plurality of light emitting elements LE including a third semiconductor layer SEM3, the second semiconductor layer SEM2, the active layer MQW, the element reflective layer RFO and the first semiconductor layer SEM1 are formed.

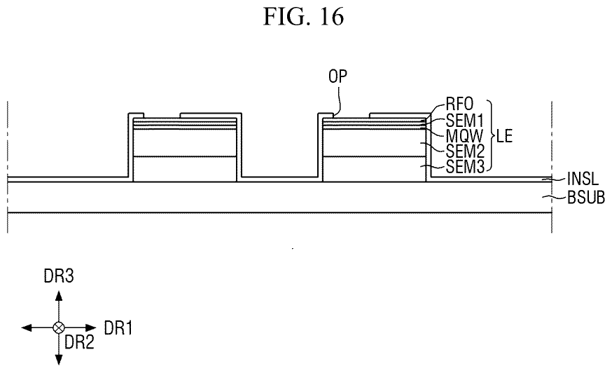

Referring to FIGS. 15 and 16, an insulating layer INS having the opening OP is formed on the base substrate BSUB on which the light emitting element LE is formed.

Specifically, the insulating material layer INSL is formed on the outer surfaces (e.g., outer peripheral or circumferential surfaces) of the plurality of light emitting elements LE. The insulating material layer INSL may be formed on the entire surface of the base substrate BSUB and may be formed not only on the light emitting element LE, but also on the top surface of the base substrate BSUB exposed by the light emitting element LE.

Then, a second etch is performed to partially remove the insulating material layer INSL to form the insulating layer INS having the opening OP on the top surface of the light emitting element LE.

Specifically, the second etch may be performed in which the insulating material layer INSL is partially removed such that the insulating material layer INSL exposes the top surface of the light emitting element LE but surrounds the sides (e.g., outer peripheral or circumferential surfaces) of the light emitting element LE. Specifically, in this process, the insulating material layer INSL may be removed to expose at least a portion of the top surface of the element reflective layer RFO of the light emitting element LE, and the top surface of the base substrate BSUB is exposed. The process of partially removing the insulating material layer INSL may be performed by a mask process.

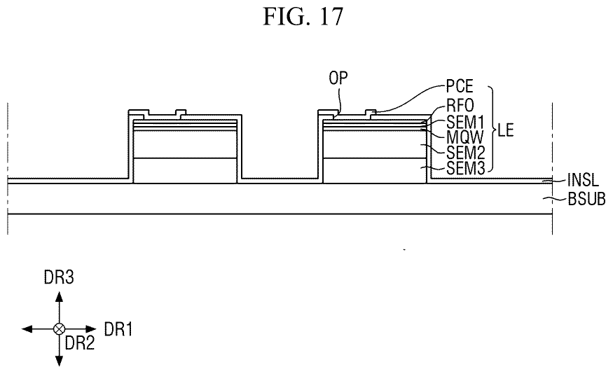

Referring to FIG. 17, the light emitting element LE may be formed by forming the pad connection electrode PCE on the element reflective layer RFO.

For example, the pad connection electrode PCE covering the opening OP of the light emitting element LE is formed by stacking a pad connection electrode material layer on the base substrate BSUB and then etching it through an etching process. The pad connection electrode material layer is formed of a conductive material and may include at least one of gold (Au), copper (Cu), tin (Sn), silver (Ag), aluminum (Al), and titanium (Ti). For example, the pad connection electrode material layer may include a 9:1 alloy, an 8:2 alloy, or a 7:3 alloy of gold and tin, or may include an alloy of copper, silver, and tin (SAC305).

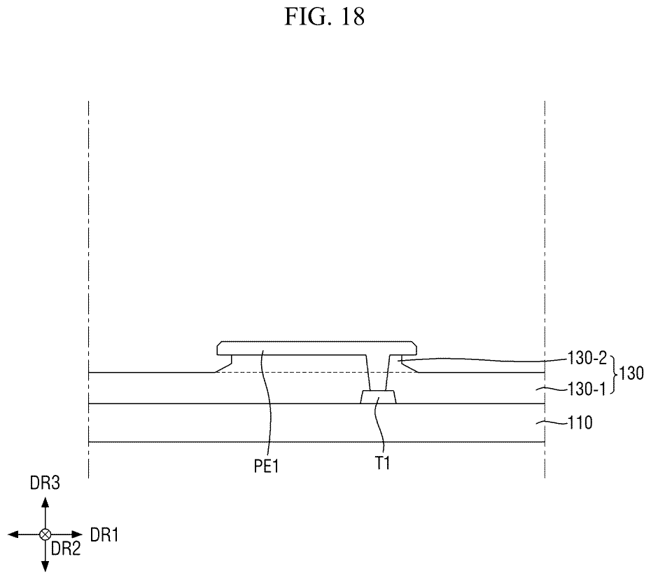

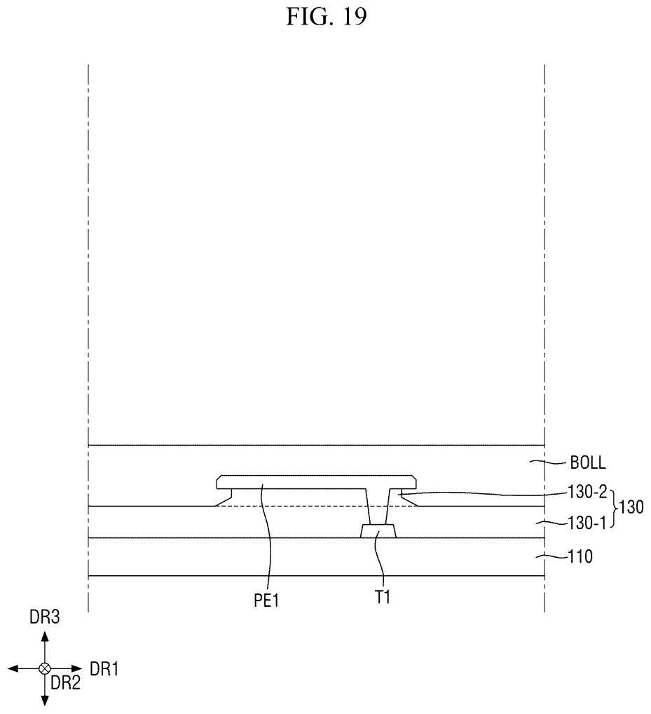

Referring to FIGS. 18 and 19, the second planarization layer 130 having an undercut-shaped structure is formed.

Specifically, the substrate 110 is prepared. As described with reference to FIG. 6, the substrate 110 may have the second planarization layer 130 and the pixel electrode PE1 formed thereon.

The second planarization layer 130 may include the first planarization unit 130-1 disposed on the substrate 110, and the second planarization unit 130-2 formed on the first planarization unit 130-1.

The second planarization unit 130-2 is etched to have the undercut structure such that a side of the second planarization unit 130-2 is positioned inwardly from a side of the pixel electrode PE1. For example, an etch process is performed by supplying an etchant to the second planarization layer 130. The second planarization unit 130-2 to which the etchant is applied is selectively etched. In one or more embodiments, the etch process time includes not only a first process time to completely remove a portion corresponding to the second planarization unit 130-2 in the region not overlapping the pixel electrode PE1, but also a second process time to form the undercut structure of the second planarization unit 130-2 in the region overlapping the pixel electrode PE1. For example, if the first process time is about 60 seconds and the second process time is a seconds, the etch process is carried out for a time of (60 seconds+α).

After the first process time, the portion corresponding to the second planarization unit 130-2 in the region not overlapping the pixel electrode PE1 is removed to expose the first planarization unit 130-1, and the sides of the second planarization unit 130-2 in the region overlapping the pixel electrode PE1 are exposed. After the second process time, the side surface of the second planarization unit 130-2 has the undercut shape that depresses inwardly.

Referring to FIGS. 19 to 21, the plurality of light emitting elements LE grown on a base substrate BSUB are transferred to the substrate 110.

Specifically, an organic pattern material layer BOLL is applied entirely on the second planarization layer 130. The organic pattern material layer BOLL may be applied to a thickness of about 2 μm but is not limited thereto. At this stage, the organic pattern material layer BOLL is not hardened and is in a fluid state, which may be referred to as a pseudo-adhesive layer.

Next, the base substrate BSUB is aligned on the substrate 110. The pad connection electrode PCE of the light emitting element LE grown on the base substrate BSUB is aligned to be disposed on the pixel electrode PE1 of the substrate 110 with the organic pattern material layer BOLL interposed therebetween. The width of the pixel electrode PE1 may be wider than the width of the light emitting element LE. The light emitting element LE may be disposed within the pixel electrode PE1.

Then, the substrate 110 and the base substrate BSUB are bonded. Specifically, the pad connection electrode PCE of the light emitting element LE 1 grown on the base substrate BSUB is in contact with the organic pattern material layer BOLL. Next, heat and pressure are applied to the organic pattern material layer BOLL to harden it. As a result, the light emitting element LE and the organic pattern material layer BOLL may be bonded. In this way, the heat and pressure of the process of curing the organic patterned material layer BOLL to bond the light emitting element LE is lower than the heat and pressure of a eutic bonding process. For example, the eutic bonding process is a relatively high temperature process of about 200 to 400 degrees Celsius, while the organic material curing process may be a relatively low temperature process of 80 to 200 degrees Celsius. Accordingly, the light emitting element LE may be bonded to the substrate 110 at a relatively lower temperature and pressure compared to the eutic bonding process.

At this time, the base substrate BSUB is separated from the plurality of light emitting elements LE.

Specifically, the base substrate BSUB is separated from the light emitting element LE. The process of separating the base substrate BSUB may be performed by a laser lift off (LLO) process. The laser lift-off process uses a laser, and a KrF excimer laser (248 nm wavelength) may be used as the light source. The energy density of the excimer laser is irradiated in the range of about 550 mJ/cm² to 950 mJ/cm², and the incident area may be in the range of 50×50 μm² to 1×1 cm² but is not limited thereto. By irradiating the laser to the base substrate BSUB, the base substrate BSUB may be separated from the light emitting element LE.

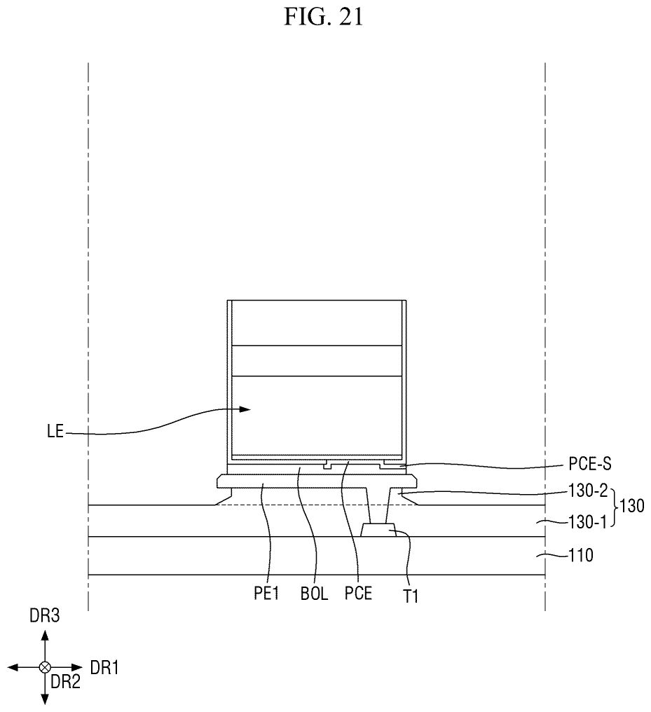

Referring to FIG. 21, the organic pattern material layer BOLL that is not overlapped with the light emitting element LE may be ashed (e.g., ashing is performed therewith) to form the organic patterned layer BOL. As the organic pattern material layer BOLL not overlapping the light emitting element LE is ashed (e.g., ashing is performed therewith), the side PCE-S of the pad connection electrode PCE disposed on one side of the light emitting element LE may be exposed.

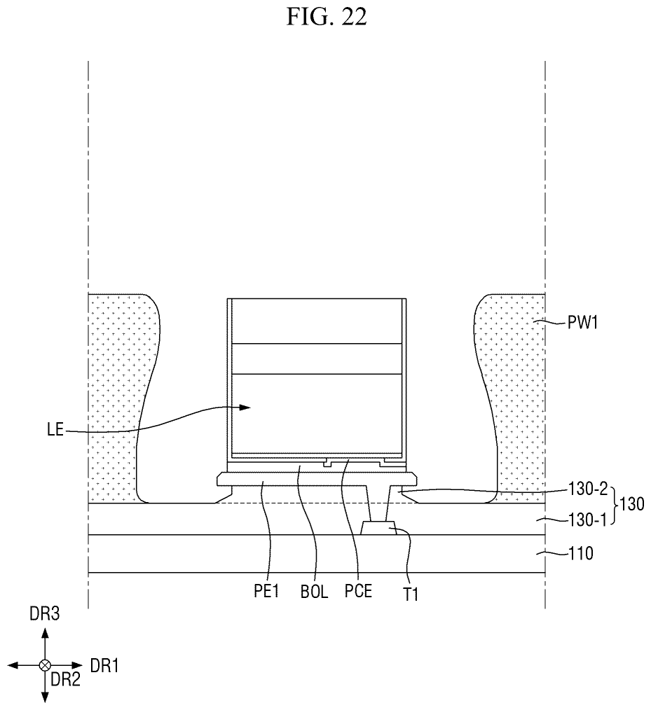

Referring to FIG. 22, a first partition wall PW1 is formed on the second planarization layer 130.

Specifically, the first partition wall PW1 is formed on the second planarization layer 130 using a negative photoresist. Because the portion of the negative photoresist that does not receive light is dissolved, the first partition wall PW1 may be formed in an inverted tapered shape that narrows in width toward the bottom.

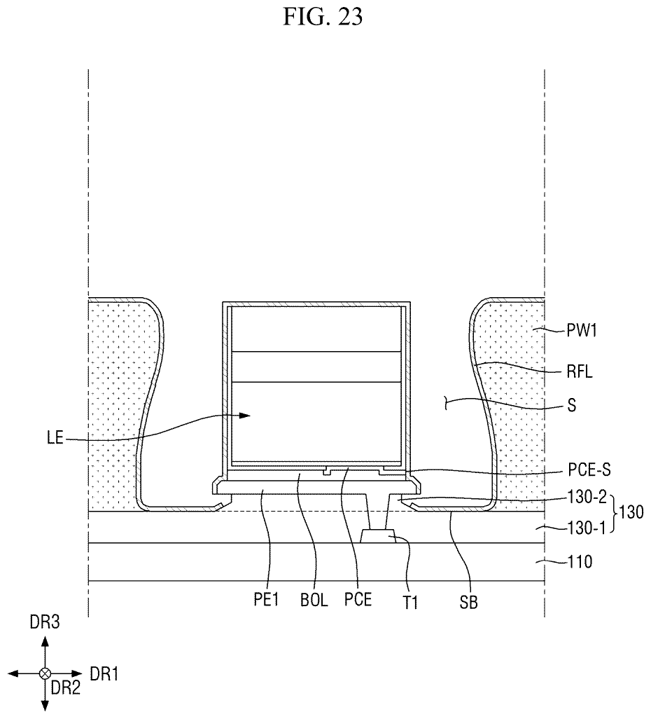

Referring to FIG. 23, the reflective material layer RFL is deposited on the entire surface of the substrate 110 on which the first partition wall PW1 is formed. The reflective material layer RFL may be formed to cover both the first partition wall PW1 and the light emitting element LE.

The reflective material layer RFL is formed on the top surface and sides of the first partition wall PW1, the top surface and sides of the light emitting element LE, as well as on the bottom (e.g., top surface of the second planarization layer 130) between the light emitting element LE and the first partition wall PW1. The reflective material layer RFL is disposed along the side of the light emitting element LE, the side PCE-S of the pad connection electrode PCE, the side of the organic pattern layer BOL, and the side of the pixel electrode PE1 but is disconnected from the reflective material layer RFL disposed on the top surface of the second planarization layer 130 by the undercut-shaped structure of the second planarization unit 130-2 of the second planarization layer 130. Specifically, the reflective material layer RFL disposed along the side of the light emitting element LE, the side PCE-S of the pad connection electrode PCE, the side of the organic pattern layer BOL, the side of the pixel electrode PE1, and the reflective material layer RFL deposited on the bottom surface SB of the space S formed by the first partition wall PW1 are discontinuously disposed. The reflective material layer RFL disposed along the side of the light emitting element LE, and the side PCE-S of the pad connection electrode PCE may be spaced from the reflective material layer RFL deposited on the bottom surface SB of the space S 1 formed by the first partition wall PW1. The reflective material layer RFL may include, for example, aluminum (Al) or silver (Ag), or may be an alloy thereof.

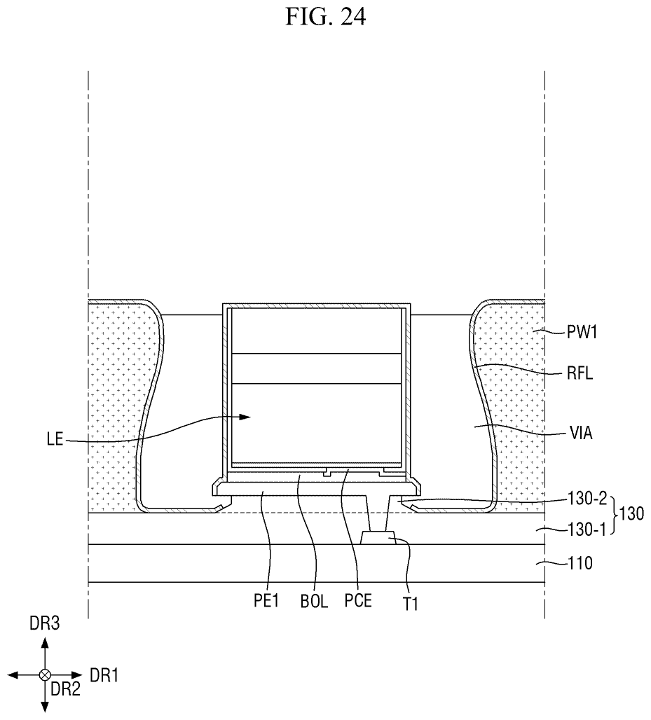

Referring to FIG. 24, the via layer VIA is formed in the space formed by the first partition wall PW1. The via layer VIA may be applied using a solution process such as spin coating or inkjet printing. The via layer VIA may be formed lower than the height of the light emitting element LE. For example, the top surface of the light emitting element LE may be exposed through the via layer VIA.

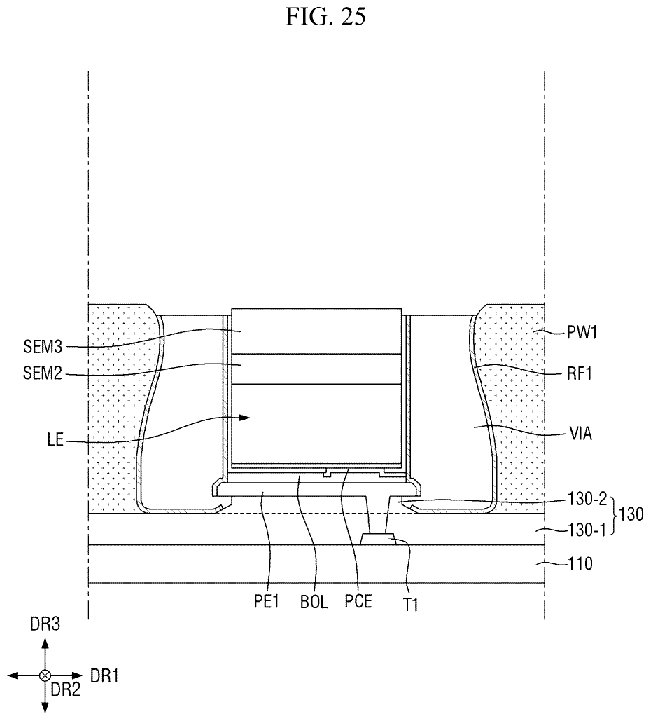

Referring to FIG. 25, the reflective material layer RFL not covered by the via layer VIA is etched to form the first reflective layer RF1. The reflective material layer RFL may be etched using a second via layer as a mask. At this time, etching may be performed by dry etching. As a result, the top surface of the light emitting element LE, that is, the third semiconductor layer SEM3, may be exposed.

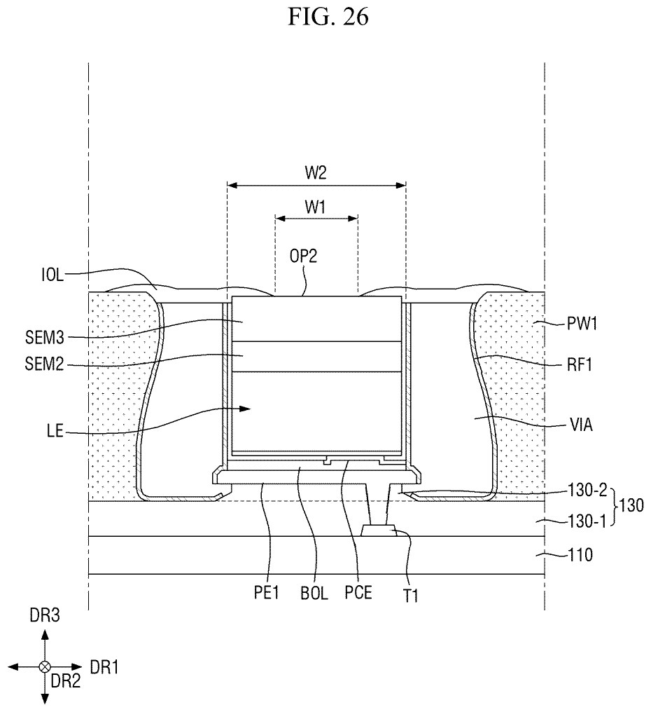

Referring to FIG. 26, the insulating organic layer IOL is formed on the via layer VIA.

Specifically, an insulating pattern material is applied to the entire substrate 110. Using a mask, at least a portion of the top of the light emitting element LE and the top of the first partition wall PW1 are etched to form an opening OP2 on the top of the light emitting element LE and the top of the first partition wall PW1. The diameter W1 of the opening OP2 formed at the top of the light emitting element LE may be about 50% or more of the diameter W2 of the light emitting element LE. The insulating organic layer IOL formed in this way may cover the entire top surface of the first reflective layer RF1.

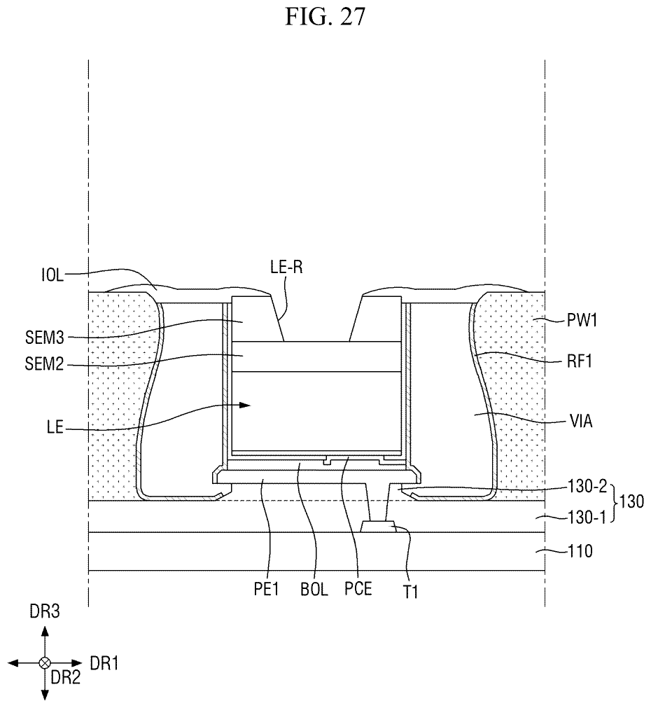

Referring to FIG. 27, a downwardly concave recess LE-R is formed on the top surface of the light emitting element LE using the insulating organic layer IOL as a mask.

Specifically, the third semiconductor layer SEM3 is dry etched using the insulating organic layer IOL as a mask. The recess LE-R has the regular tapered 1 shaped structure in which the diameter of the opening increases toward the top, and the second semiconductor layer SEM2 may be exposed by the recess LE-R.

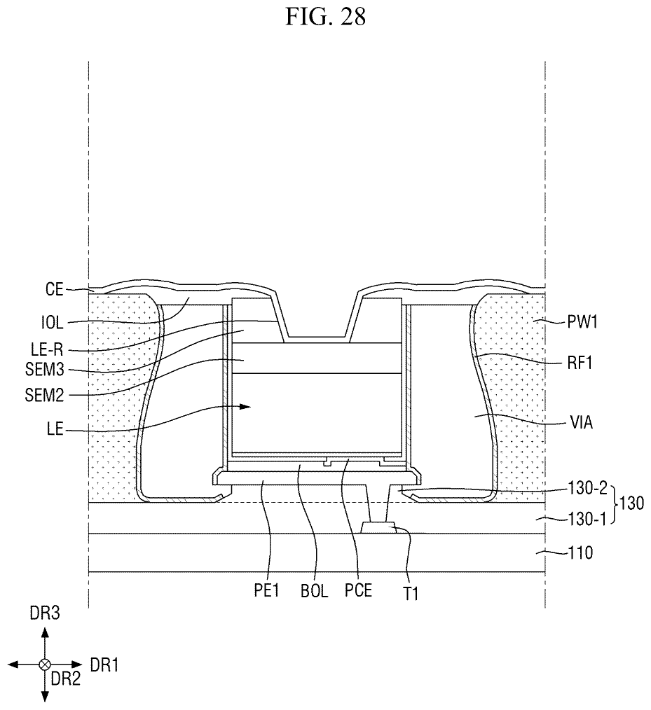

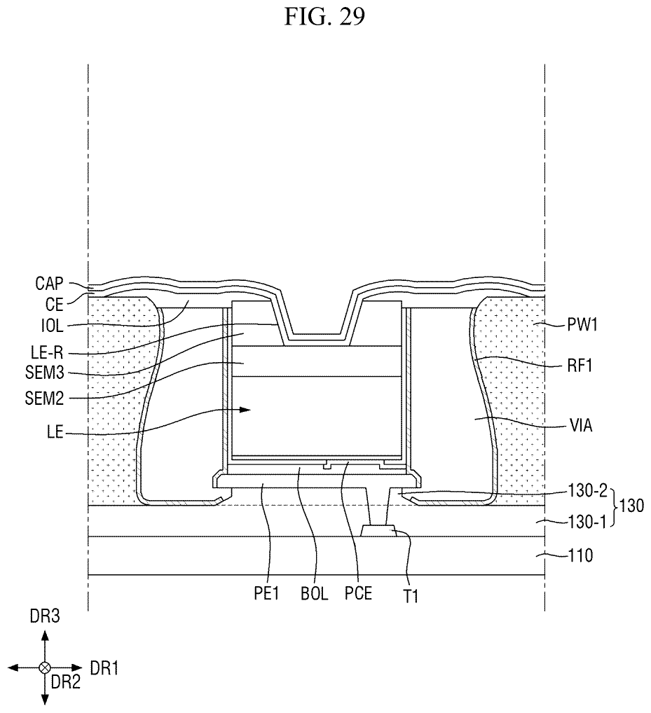

Referring to FIGS. 28 and 29, the common electrode CE and the capping layer CAP are formed on the light emitting element LE.

The common electrode CE is continuously formed throughout the display area DA. The common electrode CE covers the first partition wall PW1, the insulating organic layer IOL, and the light emitting element LE, and is in direct contact with them. The common electrode CE is formed by directly contacting the top surface of the second semiconductor layer SEM2 as well as the third semiconductor layer SEM3 of the light emitting element LE along the recess LE-R. The capping layer CAP may be formed on the entire surface of the substrate 110 to cover the common electrode CE.

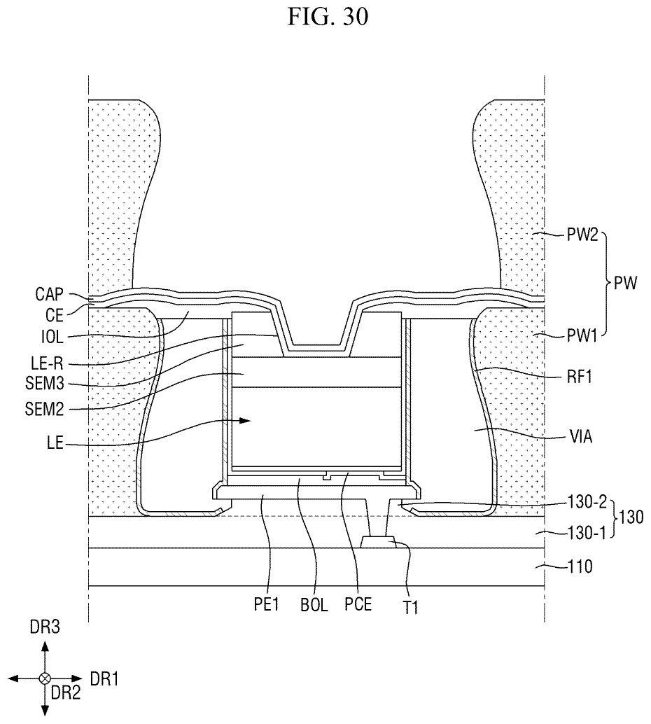

Referring to FIG. 30, the second partition wall PW2 is formed on the first partition wall PW1. The method of forming the second partition wall PW2 is the same as that of the first partition wall PW1.

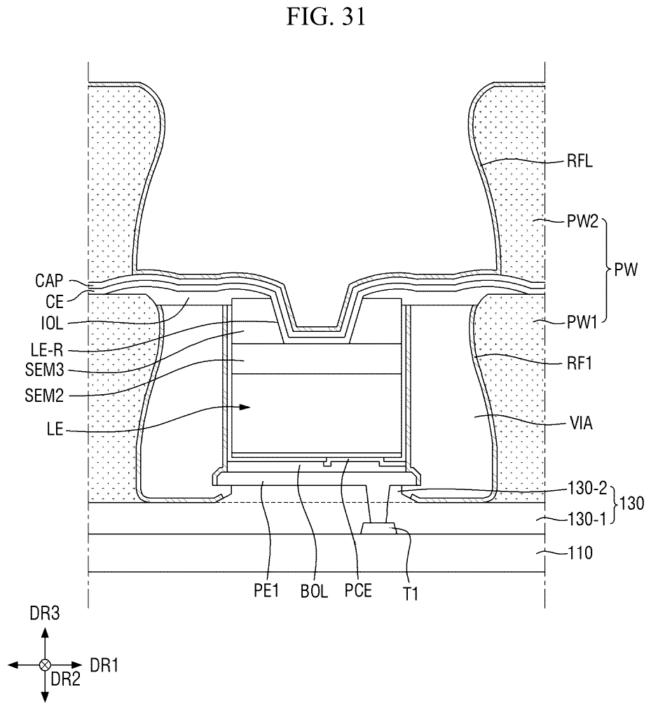

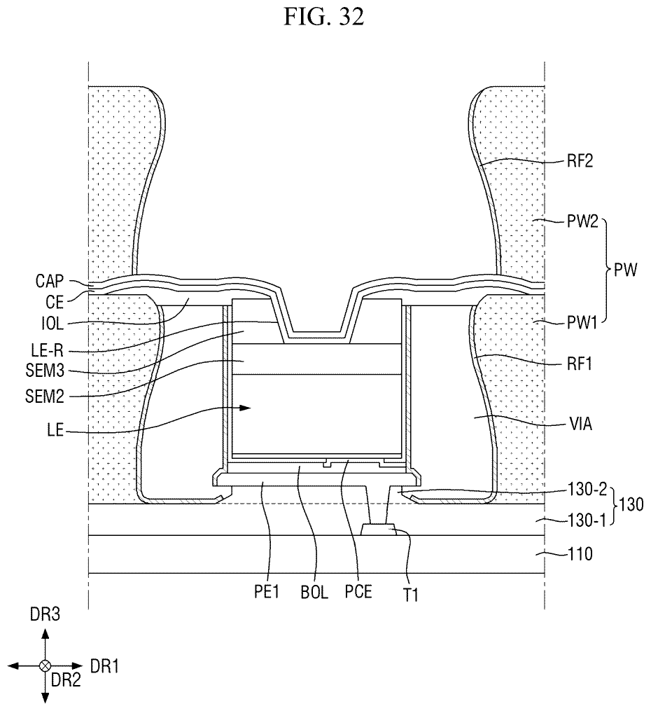

Referring to FIGS. 31 and 32, the second reflective layer RF2 is formed on the side of the second partition wall PW2.

Specifically, the reflective material layer RFL is deposited to completely cover the second partition wall PW2. Thereafter, a large voltage difference is created in the third direction DR3, and the reflective material layer RFL is etched using an etching material. In this case, the etching material moves in the third direction DR3 by voltage control, that is, moving from the top to the bottom, and may etch the reflective material layer RFL. As a result, the reflective material layer RFL disposed on the horizontal plane defined by the first direction DR1 and the second direction DR2 is removed, while the reflective material layer RFL disposed on the vertical plane defined by the third direction DR3 may not be removed. Therefore, the reflective material layer RFL disposed on the top surface of the second partition wall PW2 and the capping layer CAP is removed, leaving only the reflective material layer RFL on the side of the second partition wall PW2 to form the second reflective layer RF2.

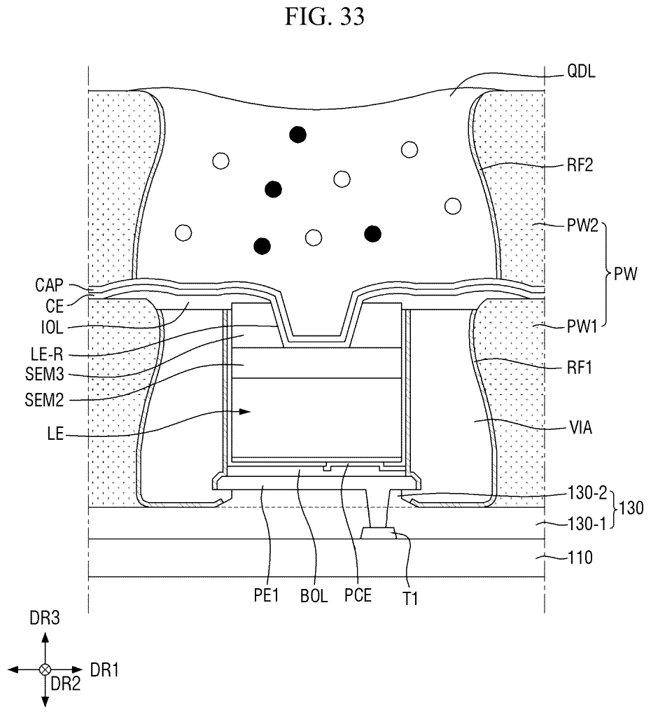

Referring to FIG. 33, the wavelength conversion layer QDL is formed in the space formed by the second partition wall PW2.

The wavelength conversion layer QDL may be formed through a solution process such as imprinting but is not limited thereto. The wavelength conversion layer QDL may be formed to fill the space formed by the second partition wall PW2.

Next, as shown in FIG. 6, the display device 10 according to one or more embodiments is manufactured by forming the color filter layer CFL on the substrate 110. The color filter layer CFL may include the first overcoat layer OC1, the first color filter CF1, and the second overcoat layer OC2.

The first color filter CF1 may be formed through a photo process. For example, the color filter layer CFL is formed by applying a color filter material layer on the wavelength conversion layer QDL and the second partition wall PW2 and patterning it through the photo process to form the first color filter CF1 that overlaps the wavelength conversion layer QDL. The thickness of the first color filter CF1 may be 1 μm or less but is not limited thereto.

According to one or more embodiments, the first reflective layer RF1 on the first partition wall PW1 and the first reflective layer RF1 on the side of the light emitting element LE may be formed in a single process while being electrically separated from each other by forming the second planarization layer 130 on which the pixel electrodes PE1, PE2, and PE3 are disposed in the undercut structure. In this way, by forming the reflective layer in the entire area around the partition wall PW and the light emitting element LE, light extraction efficiency may be improved by preventing light from being lost outside the partition wall PW.

Additionally, the second semiconductor layer SEM2 and the common electrode CE are in direct contact to reduce the contact resistance of the common electrode CE. This may improve power consumption.

In addition, the wavelength conversion layer QDL may be sufficiently formed to increase the light conversion efficiency compared to a single-layer partition wall PW by forming a multi-layer partition wall.

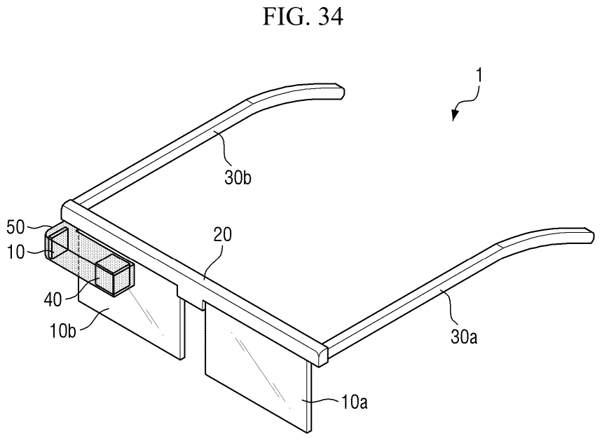

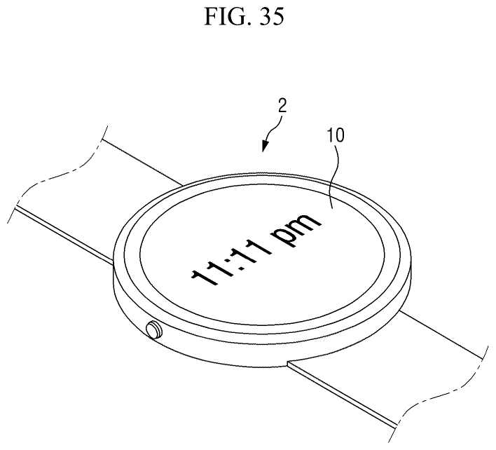

FIG. 34 is an example diagram illustrating a virtual reality device including a display device according to one or more embodiments. FIG. 34 illustrates a virtual reality device 1 in which the display device 10 according to one or more embodiments is used.

Referring to FIG. 34, the virtual reality device 1 according to one or more embodiments may be a device in a form of glasses. The virtual reality device 1 according to one or more embodiments may include a display device 10, a left-eye lens 10a, a right-eye lens 10b, a support frame 20, left and right legs 30a and 30b, a reflective member 40, and a display device housing 50.

FIG. 34 illustrates the virtual reality device 1 including the two legs 30a and 30b. However, the present disclosure is not limited thereto. The virtual reality device 1 according to one or more embodiments may be used in a head-mounted display including a head-mounted band that may be mounted on a head instead of the legs 30a and 30b. For example, the virtual reality device 1 according to one or more embodiments may not be limited to the example shown in FIG. 34, and may be applied in various forms and in various electronic devices.

The display device housing 50 may receive the display device 10 and the reflective member 40. An image displayed on the display device 10 may be reflected from the reflective member 40 and provided to a user's right eye through the right-eye lens 10b. Thus, the user may view a virtual reality image displayed on the display device 10 via the right eye.

FIG. 34 illustrates that the display device housing 50 is disposed at a right end of the support frame 20. However, one or more embodiments of the present disclosure is not limited thereto. For example, the display device housing 50 may be disposed at a left end of the support frame 20. In this case, the image displayed on 1 the display device 10 may be reflected from the reflective member 40 and provided to the user's left eye via the left-eye lens 10a. Thus, the user may view the virtual reality image displayed on the display device 10 via the left eye. As another example, the display device housing 50 may be disposed at each of the left end and the right end of the support frame 20. In this case, the user may view the virtual reality image displayed on the display device 10 via both the left eye and the right eye.

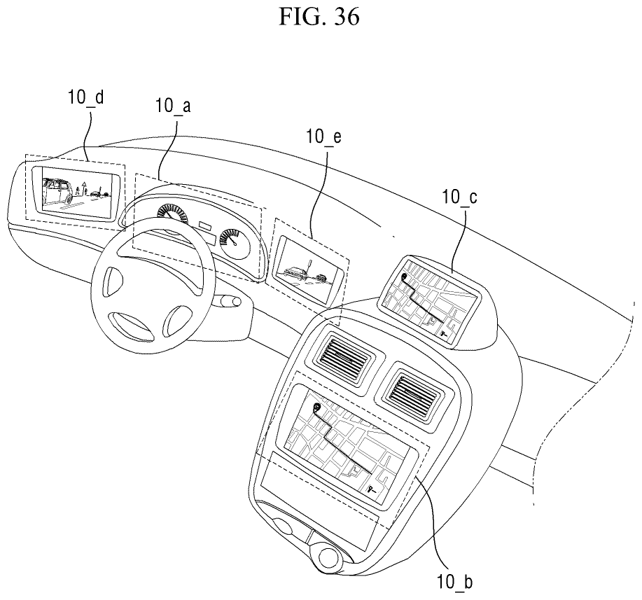

FIG. 35 is an example diagram illustrating a smart device including a display device according to one or more embodiments.

Referring to FIG. 35, a display device 10 according to one or more embodiments may be applied to a smart watch 2 as one of smart devices.

FIG. 36 is an example diagram illustrating a vehicle including a display device according to one or more embodiments. FIG. 36 illustrates a vehicle in which display devices 10_a, 10_b, 10_c, 10_d and 10_e according to one or more embodiments are used.

Referring to FIG. 36, the display devices 10_a, 10_b, and 10_c according to one or more embodiments may be applied to the dashboard of the vehicle, applied to the center fascia of the vehicle, or applied to a Center Information Display (CID) disposed on the dashboard of the vehicle. Further, each of the display devices 10_d and 10_e according to one or more embodiments may be applied to each room mirror display that replaces each of side-view mirrors of the vehicle.

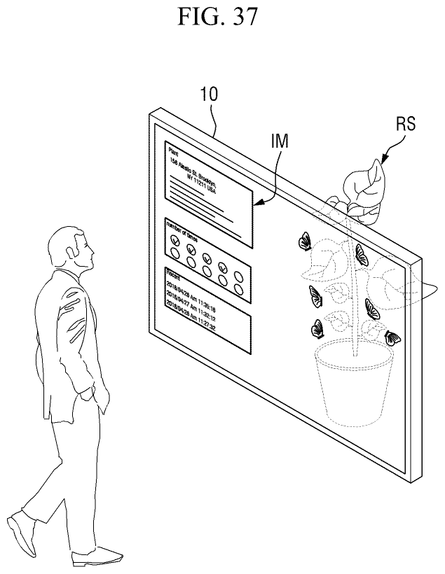

FIG. 37 is an example diagram illustrating a transparent display device including a display device according to one or more embodiments.

Referring to FIG. 37, a display device 10 according to one or more embodiments may be applied to a transparent display device. The transparent display device may transmit light therethrough while displaying an image IM thereon. Therefore, a user located in front of the transparent display device may not only view the image IM displayed on the display device 10, but also view an object RS or a background located in rear of the transparent display device. In case that the display device 10 is applied to the transparent display device, the substrate 110 of the display device 10 shown in FIG. 6 may include a light transmitting portion that may transmit light therethrough or may be made of a material that may transmit light therethrough.

In concluding the detailed description, those skilled in the art will appreciate that many variations and modifications can be made to the embodiments of the present disclosure without substantially departing from the principles and scope of the present disclosure. Therefore, the embodiments of the present disclosure are used in a generic and descriptive sense only and not for purposes of limitation.

What is claimed is:

1. A display device comprising:
a planarization layer comprising a first planarization unit on a substrate and a second planarization unit on the first planarization unit;
a pixel electrode on the second planarization unit;
an organic pattern layer on the pixel electrode;
a light emitting element on the organic pattern layer and having a downwardly convex recess on a top surface thereof;
a first partition wall on one surface of the first planarization unit and forming a space around the light emitting element;
a via layer in the space around the light emitting element;
a first reflective layer around a side of the first partition wall in the space around the light emitting element, on the first planarization unit, and around a side of the light emitting element, a side of the organic pattern layer, and a side of the pixel electrode;
an insulating organic layer covering a portion of the top surface of the light emitting element, an upper portion of the via layer, and a portion of an upper portion of the first partition wall; and
a common electrode extending along bottom and side surfaces of the recess on the top surface of the light emitting element, a top surface of the insulating organic layer, and a top surface of the first partition wall,
wherein the second planarization unit has an undercut shape in which a side surface of the second planarization unit is located towards a center of the pixel electrode from a side surface of the pixel electrode, and the first reflective layer has a discontinuous structure due to the undercut shape.

2. The display device of claim 1, wherein the light emitting element comprises a first semiconductor layer, an active layer, a second semiconductor layer, and a third semiconductor layer sequentially stacked, and wherein the recess is formed from a top surface of the third semiconductor layer to the second semiconductor layer toward the second semiconductor layer to expose a portion of the second semiconductor layer, and the common electrode is in direct contact with the exposed portion of the second semiconductor layer.

3. The display device of claim 2, wherein the light emitting element further comprises an element reflective layer on a bottom surface of the first semiconductor layer; an insulating layer around sides of the element reflective layer, the first semiconductor layer, the active layer, the second semiconductor layer, and the third semiconductor layer; and a pad connection electrode on a bottom surface of the element reflective layer and in direct contact with the element reflective layer and the first reflective layer.

4. The display device of claim 3, wherein the insulating layer is further located on the bottom surface of the element reflective layer and has an opening exposing at least a portion of the element reflective layer,
wherein the pad connection electrode contacts the element reflective layer through the opening.

5. The display device of claim 4, wherein the pad connection electrode electrically connects the first semiconductor layer and the pixel electrode through the element reflective layer and the first reflective layer.

6. The display device of claim 2, wherein one end of the insulating organic layer meets one end of the recess on the light emitting element.

7. The display device of claim 6, wherein the recess has a regular tapered shape.

8. The display device of claim 2, wherein side surfaces of the light emitting element and side surfaces of the organic pattern layer are aligned with each other.

9. The display device of claim 8, wherein the pixel electrode protrudes further outward than a side of the organic pattern layer.

10. The display device of claim 1, wherein the first partition wall has a same height as the light emitting element and has an inverted tapered shape.

11. The display device of claim 10, further comprising a second partition wall located on the first partition wall, wherein the second partition wall has a height that is equal to or shorter than that of the first partition wall and has an inverted tapered shape.

12. The display device of claim 1, wherein the recess has a width of 40% or more of a width of the light emitting element.

13. The display device of claim 1, further comprising: a capping layer on the common electrode and covering the common electrode;
a second partition wall disposed on the capping layer to overlap the first partition wall;
a second reflective layer around a side of the second partition wall; and
a wavelength conversion layer disposed in a space formed by the second partition wall.

14. The display device of claim 13, further comprising an overcoat layer and a color filter layer sequentially disposed on the wavelength conversion layer and the second partition wall.

15. A method of manufacturing display device comprising:
forming an undercut shape on a substrate on which a first planarization unit, a second planarization unit, and a pixel electrode are stacked in an order by etching the second planarization unit to expose the first planarization unit, and wherein a side of the second planarization unit is located towards a center of the pixel electrode from a side of the pixel electrode;
bonding a light emitting element by forming an organic pattern layer on the pixel electrode;
forming a first partition wall on the first planarization unit to surround the light emitting element;
depositing a reflective material layer to cover both the first partition wall and the light emitting element;
forming a via layer in a space formed by the first partition wall, and forming a reflective layer by etching a reflective material layer on an upper portion of the light emitting element not covered by the via layer;
forming an insulating organic layer having an opening on a top of the light emitting element;
forming a downwardly recessed recess on a top surface of the light emitting element by etching the light emitting element with the insulating organic layer as a mask; and
forming a common electrode in direct contact with the recess of the light emitting element.

16. The method of claim 15, wherein bonding the light emitting element by forming the organic pattern layer on the pixel electrode comprises:
fully applying an organic pattern material layer on the substrate to cover the first planarization unit and the pixel electrode;
arranging the light emitting element to be aligned with the pixel electrode on the organic pattern material layer; and
bonding the light emitting element by curing the organic pattern material layer.

17. The method of claim 16, wherein bonding the light emitting element by forming the organic pattern layer on the pixel electrode further comprises:
ashing the organic pattern material layer that is not overlapped with the light emitting element to form the organic pattern layer.

18. The method of claim 15, wherein the first partition wall comprises a negative photosensitive material and has an inverted tapered shape which has a width that decreases in a downward direction.

19. The method of claim 15, further comprising:
forming a capping layer on the common electrode to cover the common electrode;
forming a second partition wall on the capping layer to overlap the first partition wall;
forming a second reflective layer around a side surface of the second partition wall; and
forming a wavelength conversion layer in a space formed by the second partition wall.

20. The method of claim 19, further comprising:
forming an overcoat layer and a color filter layer sequentially located on the wavelength conversion layer and the second partition wall.
